(19) United States
(12) Patent Application Publication
(10) Pub. No.: US 2016/0284811 A1
(43) Pub. Date: Sep. 29, 2016

(54) ELECTRONICS INCLUDING GRAPHENE-BASED HYBRID STRUCTURES

(71) Applicant: Massachusetts Institute of Technology, Cambridge, MA (US)

(72) Inventors: Lili Yu, Cambridge, MA (US); Han Wang, White Plains, NY (US); Tomas Palacios, Belmont, MA (US)

(21) Appl. No.: 15/034,051

(22) PCT Filed: Nov. 4, 2014
(86) PCT No.: PCT/US2014/063903

§ 371 Date: May 3, 2016

Related U.S. Application Data
(60) Provisional application No. 61/899,418, filed on Nov. 4, 2013.

(51) Int. Cl. H01L 29/45; H01L 29/786; H01L 21/3205; H01L 21/3215; H01L 21/285; H01L 21/288

(52) U.S. Cl. CPC H01L 29/45; H01L 21/28506; H01L 21/288; H01L 21/32055; H01L 21/3215; H01L 29/786

(57) ABSTRACT

Device are described that include a semiconductor material layer and at least one graphene-based electrode disposed over a portion of the semiconductor material layer, such that the at least one graphene-based electrode forms an overlap region with the semiconductor material layer. The device includes a means for providing charge carriers in the at least one graphene-based electrode proximate to the overlap region, to reduce a difference between a work function of the at least one graphene-based electrode and an electron affinity of the semiconductor material layer, to reduce a Schottky barrier height between the semiconductor material layer and the at least one graphene-based electrode.

### CROSS-REFERENCES TO RELATED APPLICATIONS

This application claims priority to U.S. provisional application Ser. No. 61/899,418, filed Nov. 4, 2013, entitled “Graphene-MoS2 Hybrid Technology For Large-Scale Two-Dimensional Electronics,” which is hereby incorporated herein by reference in its entirety, including drawings.

### GOVERNMENT SUPPORT

This invention was made at least in part with government support under Grant Nos. N00014-09-1-1063 and N00014-12-1-0959 awarded by the U.S. Navy. The government has certain rights in the invention.

### BACKGROUND

The areas of applications of electronic devices based on silicon are diverse. For example, silicon devices and integrated circuits (IC) based on silicon have generated many different types of electronic devices, including transistors, high performance IC technologies, flexible electronics, display applications, large area electronics, digital medical imaging applications, and photovoltaic energy conversion devices. Transistors based on silicon have been widely used for many different applications, such as pixel addressing elements in large-area flat-panel displays, printing and scanning applications.

Silicon has remained attractive for use in electronics, since the costs associated with the manufacturing processes of these electronics can be lower than other processes. However, as Moore's law approaches its physical limit for silicon electronics, the device community has been actively searching for new material options that can push electronics beyond its traditional boundaries.

### SUMMARY

The Inventors have recognized and appreciated that graphene structures, including graphene structures having as few as a single atomic layer, can be exploited to generate many different types of electronic structures. They have also recognized and appreciated that graphene can be configured to exhibit high intrinsic carrier mobility, high thermal conductivity, high Young's module, and high optical transmittance (˜97.7%). Accordingly, the Inventors have developed graphene-based contacts and interconnects that are highly conductive (both electrical and thermal), durable, and transparent, enabling promising applications in various types of electronics. For example, the Inventors have developed novel ways of using the graphene-based electrodes as the contact materials, instead of or in addition to metals or metal oxides, can provide more robust electronics.

The Inventors have also recognized and appreciated that electronics based on graphene-semiconductor heterostructures can be configured to exploit the advantage of a graphene-based material as a contact material for electronic systems, such as but not limited to 2D electronic systems, 3D electronic systems, and other forms of integrated electronic systems. Example systems, apparatus and methods according to the principles described herein provide electrodes formed from a graphene-based material that can be caused to exhibit continuously-varying values of work function. As a result, a graphene-based electrode can be configured to have a value of electron affinity that greatly reduces or even substantially eliminates a Schottky barrier between the graphene-based electrode and many different types of semiconductor materials. The presence of the Schottky barrier can impede flow of charge carriers between the semiconductor and the metal. Unless the charge carriers possess an amount of energy at least high enough to overcome the Schottky barrier height (i.e., greater than about qφ_{B}), the Schottky barrier can have a rectifying effect. Reduction of the Schottky barrier height facilitates greater charge transfer between the semiconductor material and the metal material. A graphene-based material can be configured according to the principles described herein such that the Schottky barrier height between the graphene-based material and many different types of semiconductor material is reduced, including being reduced to a minimum. This provides significantly greater flexibility in the fabrication of electronic devices, since it simplifies the type of materials used as the contact and/or interconnect in the electronic devices.

In view of the foregoing, the Inventors have recognized and appreciated that electronics based on graphene, such as but not limited to transistor or other semiconductor devices, would be beneficial. Accordingly, various embodiments are directed generally to electronics based on graphene-based electrodes with tunable work functions.

Accordingly, example systems, methods, and apparatus herein provide an example device that includes a semiconductor material layer, at least one graphene-based electrode, disposed over a portion of the semiconductor material layer, such that the at least one graphene-based electrode forms an overlap region with the semiconductor material layer, and a means for providing charge carriers in the at least one graphene-based electrode proximate to the overlap region, to reduce a difference between a work function of the at least one graphene-based electrode and either (i) the energy of the electronic conduction band of the semiconductor material layer or (ii) the energy of the electronic valence band of the semiconductor material layer.

In an example, the means for providing the charge carriers includes a conductive electrode disposed in electrical communication with the at least one graphene-based electrode.

For example, the conductive electrode can include one or more of gold, palladium, platinum, copper, tantalum, tin, tungsten, titanium, tungsten, cobalt, chromium, silver, nickel, aluminum, heavily doped silicon, poly-silicon, or any combination thereof.

In an example, the means for providing the charge carriers comprises an amount of a dopant provided in at least a portion of the at least one graphene-based electrode. The dopant can be an acceptor dopant or a donor dopant.

For example, the dopant can include at least one of H₂SO₄, HCl, HNO₃, AuCl₃, FeCl₃, MoCl₂, PdCl₂, N-phenyl-bis(trifluoromethane sulfonyl)imide (PTFSI), silver bis(trifluoromethane sulfonyl)imide (STFSI), bis(trifluoromethane sulfonyl)amine, 1,5-naphthalenediamine (Na—NH2), 9,10-dimethylanthracene (An-CH3), 9,10-dibromoanthracene (An-Br), and tetrasodium 1,3,6,8-pyrenetetrasulfonic acid (TPA), hydrazine (N₂H₄), MoO₃, ReO₃, Rb₂CO₃, Cs₂CO₃, potassium, and aluminum oxide.

In an example, the semiconductor material layer can be a portion of a transistor device structure, a p-n junction device, a light-emitting device (LED), a bolometer, a solar cell, or a laser.

In an example, the example device can further include a gate electrode in electrical communication with the semiconductor material layer and spaced apart from the at least one graphene-based electrode.

Example systems, methods, and apparatus herein also provide an example device that includes a semiconductor material layer, a first graphene-based electrode in electrical communication with a first portion of the semiconductor material layer such the first graphene-based electrode forms a first overlap region with the semiconductor material layer, and a second graphene-based electrode in electrical communication with a second portion of the semiconductor material layer different from the first portion, such that the second graphene-based electrode forms a second overlap region with the semiconductor material layer. The first graphene-based electrode comprises an amount of a first dopant proximate to the first overlap region in a first concentration that reduces a Schottky barrier height between the semiconductor material layer and the first graphene-based electrode. The second graphene-based electrode comprises an amount of a second dopant proximate to the second overlap region in a second concentration that reduces a Schottky barrier height between the semiconductor material layer and the second graphene-based electrode.

In an example, the semiconductor material layer includes a p-n junction, wherein the first graphene-based electrode forms the first overlap region with the p-doped portion of the semiconductor material layer, and wherein the second graphene-based electrode forms the second overlap region with the n-doped portion of the semiconductor material layer.

In this example, the first dopant can be a p-type dopant, and the second dopant can be a n-type dopant.

Example systems, methods, and apparatus herein also provide an example device that includes a semiconductor material layer, a first graphene-based electrode in electrical communication with a first portion of the semiconductor material layer such the first graphene-based electrode forms a first overlap region with the semiconductor material layer, a dielectric material disposed over the first graphene-based electrode, a first conductive electrode in electrical communication with the dielectric material, to apply a non-zero potential difference at the first overlap region to modify a first carrier concentration of the first graphene-based electrode and modify a Schottky barrier height between the semiconductor material layer and the first graphene-based electrode, and a second conductive electrode disposed over a second portion of the semiconductor material.

In an example, the example device can further include a second graphene-based electrode disposed between the second conductive electrode and the second portion of the semiconductor material layer, where the second graphene-based electrode is in electrical communication with the second portion of the semiconductor material layer such the second conductive electrode forms a second overlap region with the semiconductor material layer, where the semiconductor material layer comprises a p-n junction, where the first graphene-based electrode forms the first overlap region with the n-doped portion of the semiconductor material layer, and where the second graphene-based electrode forms the second overlap region with the p-doped portion of the semiconductor material layer.

In this example, the example device can further include a first dielectric material disposed between the first graphene-based electrode and the first conductive electrode, and a second dielectric material disposed between the second graphene-based electrode and the second conductive electrode.

In an example, the example device can further include a means to apply a positive voltage the first conductive electrode, and a means to apply a negative voltage to the second conductive electrode.

In an example, the example device can further include a dielectric material disposed between the second conductive electrode and the second portion of the semiconductor material layer, where the second conductive electrode is a gate electrode.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A shows example energy diagrams of a semiconductor and a metal, according to principles of the present disclosure.

FIG. 1B shows example energy diagrams of a semiconductor in contact with a metal, with formation of a Schottky barrier at the metal-semiconductor interface, according to principles of the present disclosure.

FIG. 1C shows an example of the work functions of various metals as compared to the energy levels of 4H—SiC, according to principles of the present disclosure.

FIG. 1D shows an example plot of the work function of a graphene material vs. carrier concentration, from n-type doping (above dashed line), intrinsic material, and p-type doping (below dashed line), according to principles of the present disclosure.

FIG. 2A-2C show example schematic views of example semiconductor devices including a graphene-semiconductor heterostructure, according to principles of the present disclosure.

FIG. 3A shows a top view of an example semiconductor device including a graphene-semiconductor heterostructure, according to principles of the present disclosure.

FIG. 3B-3E show cross-sectional views of example semiconductor devices including a graphene-semiconductor heterostructure, according to principles of the present disclosure.

FIG. 4A-4C show cross-sectional views of example semiconductor devices including a graphene-semiconductor heterostructure, according to principles of the present disclosure.

FIG. 5A-5B show cross-sectional views of example semiconductor devices including a graphene-semiconductor, according to principles of the present disclosure.

FIG. 6A shows an example chemical vapor deposition (CVD) apparatus to produce an example molybdenum disulfide (MoS₂) semiconductor material, according to principles of the present disclosure.

FIG. 6B-6C show images of example MoS₂ semiconductor material layers produced using a CVD process at different locations on a substrate, according to principles of the present disclosure.

FIG. 6D shows an atomic force microscopy (AFM) image of an example MoS₂ semiconductor material produced using a CVD process, according to principles of the present disclosure.

FIG. 6E shows a plot of a surface height profile vs. distance of an example MoS₂ semiconductor material on a substrate, according to principles of the present disclosure.

FIG. 6F shows an optical image micrograph and an atomic force microscope (AFM) image (inset) of an example MoS₂ semiconductor material produced using a CVD, according to principles of the present disclosure.

FIG. 6G shows example Raman spectra of an example MoS₂ semiconductor material and a graphene-MoS₂ heterostructure, according to principles of the present disclosure.

FIG. 7A shows an optical micrograph of an example graphene-based material produced using a CVD process, according to principles of the present disclosure.

FIG. 7B shows Raman spectra of an example graphene-based material and a graphene-MoS₂ heterostructure, according to principles of the present disclosure.

FIG. 8A-8C show example stages in the fabrication of an example electronic structure based on a graphene-MoS₂ heterostructure, according to principles of the present disclosure.

FIG. 8D shows an optical micrograph and an AFM image (inset) of an example transistor including a graphene-MoS₂ heterostructure, according to principles of the present disclosure.

FIG. 8E is an optical micrograph of example large-scale chips of MoS₂ devices and circuits including graphene heterostructures, according to principles of the present disclosure.

FIG. 9A-9D show plots of transport properties of an example transistor based on a graphene-MoS₂ heterostructure (MoS₂+G) and an example transistor based on MoS₂ and titanium (MoS₂+Ti), according to principles of the present disclosure.

FIG. 9E shows a plot of dV_{d}/dI_{d} vs. 1/I_{d} for an example transistor based on MoS₂ and titanium, with a back gate voltage of about 40 volts, according to principles of the present disclosure.

FIG. 10A-10B show example of output and transfer characteristics of an example graphene-semiconductor heterostructure, according to principles of the present disclosure.

FIG. 10C shows a plot of output voltage as a function of the input voltage for an example MoS₂-graphene logic inverter and an optical image of the example inverter (inset), according to principles of the present disclosure.

FIG. 10D shows a plot of the gain of the example inverter of FIG. 10C, according to principles of the present disclosure.

FIG. 10E-10F show plots of the top gate performance of an example MoS₂-graphene transistor, according to principles of the present disclosure.

FIG. 11A-11D show plots of temperature dependent transport of an example MoS₂-graphene transistor and an example MoS₂—Ti transistor, according to principles of the present disclosure.

FIG. 11E shows a plot of transconductance vs. back gate overdrive and threshold voltage at various temperatures of an example MoS₂-graphene transistor, according to principles of the present disclosure.

FIG. 11F shows threshold voltages of an example MoS₂-graphene transistor at different temperatures (based on FIG. 11E), according to principles of the present disclosure.

FIG. 11G shows transconductance versus back gate voltage at various temperatures for an example MoS₂—Ti transistor, according to principles of the present disclosure.

FIG. 12A shows a plot of gate-dependent Schottky barrier height of an example MoS₂-graphene transistor and an example MoS₂—Ti transistor, according to principles of the present disclosure.

FIG. 12B shows a cross-sectional view of an example MoS₂-graphene transistor, according to principles of the present disclosure.

FIG. 12C shows energy band diagrams of example MoS₂-graphene heterostructures at differing values of back gate voltages, according to principles of the present disclosure.

FIG. 13 shows example computed values of Schottky barrier height as a function of bias voltage at different values of charge carrier doping levels, according to principles of the present disclosure.

FIG. 14A shows a plot of example computed plane-averaged electron density differences along the direction perpendicular to an example graphene-MoS₂ interface, according to principles of the present disclosure.

FIG. 14B shows example isosurfaces corresponding to the electron density differences shown in FIG. 14A, according to principles of the present disclosure.

FIG. 14C-14D show computed band structures at zero bias voltage of example MoS₂-graphene heterostructures at different doping levels, according to principles of the present disclosure.

FIG. 14E shows a computed band structure of an example MoS₂-graphene heterostructure at a similar doping level to the example of FIG. 14D, at a bias voltage of 80 volts, according to principles of the present disclosure.

FIG. 15 shows an example of an arrangement of elements in an addressable array, according to principles of the present disclosure.

### DETAILED DESCRIPTION

Following below are more detailed descriptions of various concepts related to, and embodiments of, inventive methods, apparatus, and systems including flexible high-voltage thin film transistors, and image sensors and other devices based thereon. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

As used herein, the term “includes” means includes but is not limited to, the term “including” means including but not limited to. The term “based on” means based at least in part on.

With respect to substrates or other surfaces described herein in connection with various examples of the principles herein, any references to “top” surface and “bottom” surface are used primarily to indicate relative position, alignment and/or orientation of various elements/components with respect to the substrate and each other, and these terms do not necessarily indicate any particular frame of reference (e.g., a gravitational frame of reference). Thus, reference to a “bottom” of a substrate or a layer does not necessarily require that the indicated surface or layer be facing a ground surface. Similarly, terms such as “over,” “under,” “above,” “beneath” and the like do not necessarily indicate any particular frame of reference, such as a gravitational frame of reference, but rather are used primarily to indicate relative position, alignment and/or orientation of various elements/components with respect to the substrate (or other surface) and each other. The terms “disposed on” and “disposed over” encompass the meaning of “embedded in,” including “partially embedded in.” In addition, reference to feature A being “disposed on,” “disposed between,” or “disposed over” feature B encompasses examples where feature A is in contact with feature B, as well as examples where other layers and/or other components are positioned between feature A and feature B.

Example systems, apparatus, and methods described herein provide electronic devices based on graphene-semiconductor heterostructures. An example device according to the principled herein can include a semiconductor layer, a graphene-based electrode disposed over and forming an overlap region with the semiconductor layer, and a conductive layer disposed in electrical communication with the graphene-based electrode. A voltage applied across the conductive layer can be used to modify the Schottky barrier height between the semiconductor layer and the graphene-based electrode and improve the ohmic contact with the semiconductor layer. Another example device according to the principled herein can include a semiconductor layer and a graphene-based electrode disposed over and forming an overlap region with the semiconductor layer, where the graphene-based electrode includes an amount of a dopant to change the charge carrier type and/or concentration of the graphene-based electrode, to modify the Schottky barrier height and improve the ohmic contact with the semiconductor layer.

As used herein, the term “electrical communication” includes electrical contact between components (either directly or across one or more intermediate components), resistive contact, ohmic contact, and/or capacitive coupling (including capacitive coupling across a dielectric).

Example systems, apparatus, and methods described herein provide yet another example device that can include a semiconductor layer, a graphene-based electrode disposed over and forming an overlap region with the semiconductor layer, and a conductive layer disposed in electrical communication with the graphene-based electrode. The graphene-based electrode can be configured to include an amount of a dopant to change the charge carrier type and/or concentration of the graphene-based electrode, to modify the Schottky barrier height and improve the ohmic contact with the semiconductor layer. In addition, a voltage can be applied across the conductive layer can be used to further modify the Schottky barrier height between the semiconductor layer and the graphene-based electrode and further improve the ohmic contact with the semiconductor layer.

In an example, an electronic device according to an example systems, apparatus, and methods described herein includes a semiconductor layer, at least two graphene-based electrodes disposed over and forming a different respective overlap region with the semiconductor layer, and at least two conductive layers, each conductive layer being disposed in electrical communication with one of the graphene-based electrodes. Each graphene-based electrode may be independently operated to tune the Schottky barrier height at the respective overlap region. For example, the voltage applied across a first one of the conductive layers to modify the Schottky barrier height at the first respective overlap region can have a different magnitude and/or sign (direction) than the voltage applied across a second one of the conductive layers.

Based on the example systems, apparatus, and methods described herein, electronic devices (including two dimensional devices) can be constructed using graphene and one-atom thick layers of semiconductor materials. In a non-limiting example, a chemical vapor deposition technique or a 3D printing technique can be employed for the fabrication.

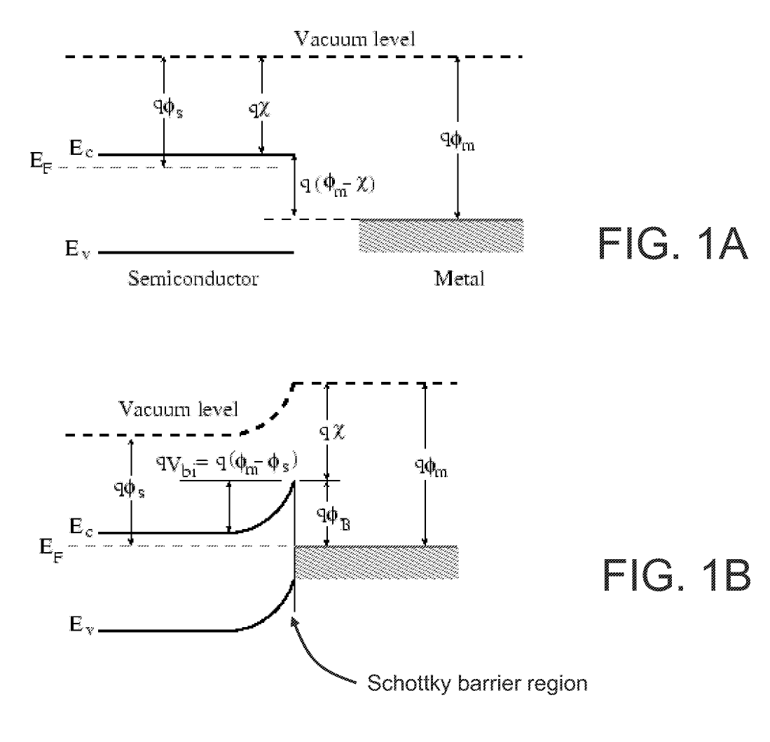

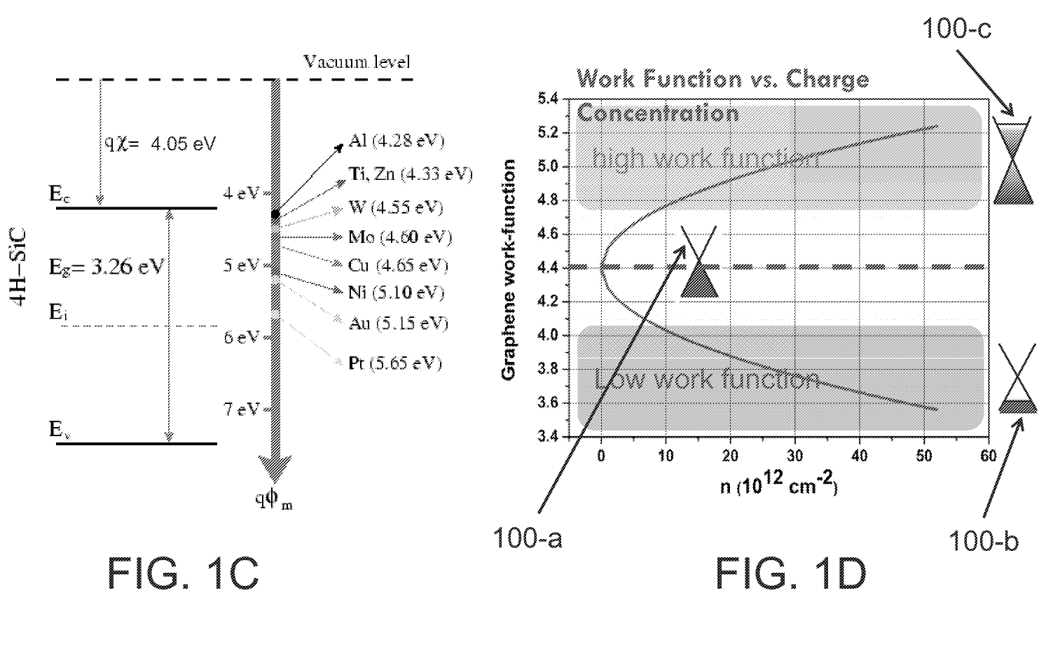

FIG. 1A shows example energy diagrams of a semiconductor material and a metal material that are not in contact with each other. On the left side of FIG. 1A, an example energy diagram of a semiconductor material is shown to include a valence level (Eᵥ), a conduction level (E_{c}), a Fermi level (E_{F}), and a vacuum level, as readily understood in the art. Without being bound by any theory or mode of operation, the energy difference between the vacuum level and the Fermi level can be defined as a surface potential (qφₛ) of the semiconductor material, and the energy different between the vacuum level and the conduction level can be defined as an electron affinity (qχ) of the semiconductor material, where q is the charge of an electron. On the right side of the FIG. 1A, an example energy diagram of a metal material is shown to include a Fermi level (E_{F}) and a vacuum level, with the energy different between the vacuum level and the Fermi level being defined as a work function (qφₘ) of the metal material. In the example of FIG. 1A, the Fermi level of the example semiconductor material is shown to be higher than the Fermi level of the example metal material.

FIG. 1B shows example energy diagrams of the semiconductor material and the metal material depicted in FIG. 1A while they are in contact with each other to form a heterostructure. The contact between the two materials can result in an alignment of their Fermi levels, a downward shift in the energy diagram of the semiconductor material, and definition of a Schottky barrier proximate to the interface of the semiconductor material and the metal, as depicted in FIG. 1B. The Schottky barrier height (qφ_{B}) can be defined differently for a n-type semiconductor material in contact with a metal material, as compared to a p-type semiconductor material in contact with a metal material. For a n-type semiconductor material in contact with a metal material, the Schottky barrier height (qφ_{B}) can be computed based on the following expression:

φ_{B}=φₘ−χ,

where φₘ is determined based on the work function of the metal material, and χ is determined based on the electron affinity of the semiconductor material (qχ). For a p-type semiconductor material in contact with a metal material, the Schottky barrier height (qφ_{B}) can be computed based on the following expression:

φ_{B}=E_{g}/q+χ−φₘ,

where E_{g}=E_{c}−Eᵥ is the energy band gap of the semiconductor material, χ is determined based on the electron affinity of the semiconductor material (qχ), and φₘ is determined based on the work function of the metal material.

The presence of the Schottky barrier can impede flow of charge carriers between the semiconductor and the metal. Unless the charge carriers possess an amount of energy at least high enough to overcome the Schottky barrier height (i.e., greater than about gφ_{B}), the Schottky barrier can have a rectifying effect. Reduction of the Schottky barrier height facilitates greater charge transfer between the semiconductor material and the metal material.

The Schottky barrier height can be reduced by using a metal material that has a work function similar in magnitude to the electron affinity of the semiconductor material. FIG. 1C shows example values of work function for several metal materials, including aluminum (Al), titanium (Ti), zinc (Zn), tungsten (W), molybdenum (Mo), copper (Cu), nickel (Ni), gold (Au), and platinum (Pt). The energy diagram of 4H—SiC is also shown in FIG. 1C for comparison. Using aluminum, for example, as an electrode material for contact with the 4H—SiC semiconductor material of a device can result in a lower Schottky barrier height than using gold or copper as the electrode material. None of these metal materials has a work function equivalent to the electron affinity of 4H—SiC. Moreover, the work function of a metal generally can take on only discrete values, and the work function is substantially fixed once the metal material is selected. Therefore, the electronic structure of a semiconductor material can dictate and limit the types of metal materials that can be used as a contact.

Example systems, apparatus and methods according to the principles described herein provide electrodes formed from a graphene-based material that can be caused to exhibit continuously-varying values of work function. As a result, a graphene-based electrode can be configured to have a value of electron affinity that greatly reduces or even substantially eliminates a Schottky barrier between the graphene-based electrode and many different types of semiconductor materials. For example, the graphene-based material can be configured according to the principles described herein such that the Schottky barrier height between the graphene-based material and many different types of semiconductor material is reduced, including being reduced to a minimum. This provides significantly greater flexibility in the fabrication of electronic devices, since it simplifies the type of materials used as the contact and/or interconnect in the electronic devices. As non-limiting examples, according to the principles herein, the work function of a graphene-based electrode could be tuned such that the Schottky barrier height between the graphene-based material and semiconductor materials such as silicon or GaN is reduced, including being reduced to a minimum. Furthermore, graphene-based materials can be fabricated using many different types of techniques, including CMOS fabrication techniques, chemical vapor deposition techniques, and direct printing techniques, such as but not limited to extrusion using 3D printing techniques (e.g., of graphene flakes). This facilitates direct printing of components of the electronic structures.

The example systems, apparatus and methods provide for regulation of at least one of (i) the concentration of charge carriers in the graphene-based material, and (ii) the type of charge carriers in the graphene-based material, to cause the graphene-based material to exhibit continuously-varying values of work function. Example systems, apparatus and methods described herein facilitate the tuning of the work function of the graphene-based material, such that the Schottky barrier height between the graphene-based material and a semiconductor material can be reduced, including being reduced to a minimum. As a result, a more ohmic contact between the graphene-based material and the semiconductor material of a heterostructure can be derived. The performance (including but not limited to the current output) of a semiconductor device based on the graphene-based material-semiconductor material heterostructure can be increased, based on the reduced (or substantially eliminated) Schottky barrier.

As defined herein, the term “graphene-based material” encompasses any one or more of a single-layered graphene structure, a multi-layered graphene structure, a graphitic material, or any other carbon-based material or other material in the art that has an energy dispersion curve similar to the energy band diagram(s) shown in FIG. 1D. As non-limiting examples, the graphene-based material can include other nanoscale systems of carbon, including single-walled and multi-walled carbon nanotubes, nanofibers, nanohorns, nanoscale heterojunction structures, graphene-based nanostructures, and carbon nanoribbons (including graphene nanoribbons and graphitic nanoribbons), or other conductive carbon-based material. In any of the examples herein, the graphene-based material can be formed from an electrically non-conductive material that includes a coating or other layer of an electrically conductive material.

FIG. 1D shows an example plot of the values of work function (y-axis) of a graphene-based structure based on charge carrier type and charge carrier concentration (x-axis). FIG. 1D also shows the energy band diagram (100-i, i=a, b, c) of a graphene-based material about the Dirac point. As shown at 100-a, the work function is about 4.4 eV for an intrinsic graphene-based material (where the value of n=0 on the x-axis corresponds to the intrinsic carrier concentration). The value of work function decreases monotonically below 4.4 eV (the lower half of the curve in FIG. 1D) for an increasing concentration of holes as the charge carrier type, as depicted in the energy band diagram 100-b. That is, for increasing carrier concentration (introduced surface charge carrier concentration) from n=0 to about 50×10¹² cm⁻², the work function of the graphene-based material can be decreased to less than about 3.6 eV. On the other hand, the value of work function increases monotonically above 4.4 eV (upper half of the curve in FIG. 1D) for an increasing concentration of electrons as the charge carriers, as depicted in the energy band diagram 100-c. For increasing carrier concentration from n=0 to about 50×10¹² cm⁻², the work function of the graphene-based material can be increased to more than about 5.2 eV.

Based on the principles herein that facilitate tuning of the value of work function for a graphene-based material over a wide range of values, the work function of a graphene-based electrode can be tuned to approximately equate the electron affinity of several different types of semiconductor materials, resulting in a reduction of the Schottky barrier height. Using the example systems, apparatus and methods according to the principles described herein, and as shown in the plot of FIG. 1D, the work function of an electrode formed from a graphene-based material can be tuned to approximate the electron affinity of semiconductor materials such as, but not limited to, silicon (about 4.05 eV), MoS₂ (about 4.2 eV), aluminum gallium arsenide (about 3.77 eV), gallium arsenide (about 4.07 eV), germanium (about 4.13 eV), cadmium telluride (about 4.28 eV), indium antimonide (about 4.59 eV), gallium antimonide (about 4.06 eV), and indium arsenide (about 4.9 eV). As a result, a semiconductor device based on a graphene-semiconductor heterostructure according to the principles described herein can be configured to exhibit better performance than their metal-semiconductor counterparts.

According to the principles described herein, the example systems, apparatus and methods provide a device including a semiconductor material layer and a graphene-based electrode disposed over a portion of the semiconductor material layer, such that the graphene-based electrode forms an overlap region with the semiconductor material layer. The example device also includes a means for providing charge carriers in the at least one graphene-based electrode proximate to the overlap region, to reduce a difference between the work function of the graphene-based electrode and (i) the energy of the electronic conduction band of the semiconductor material layer, or (ii) the energy of the electronic valence band of the semiconductor material layer.

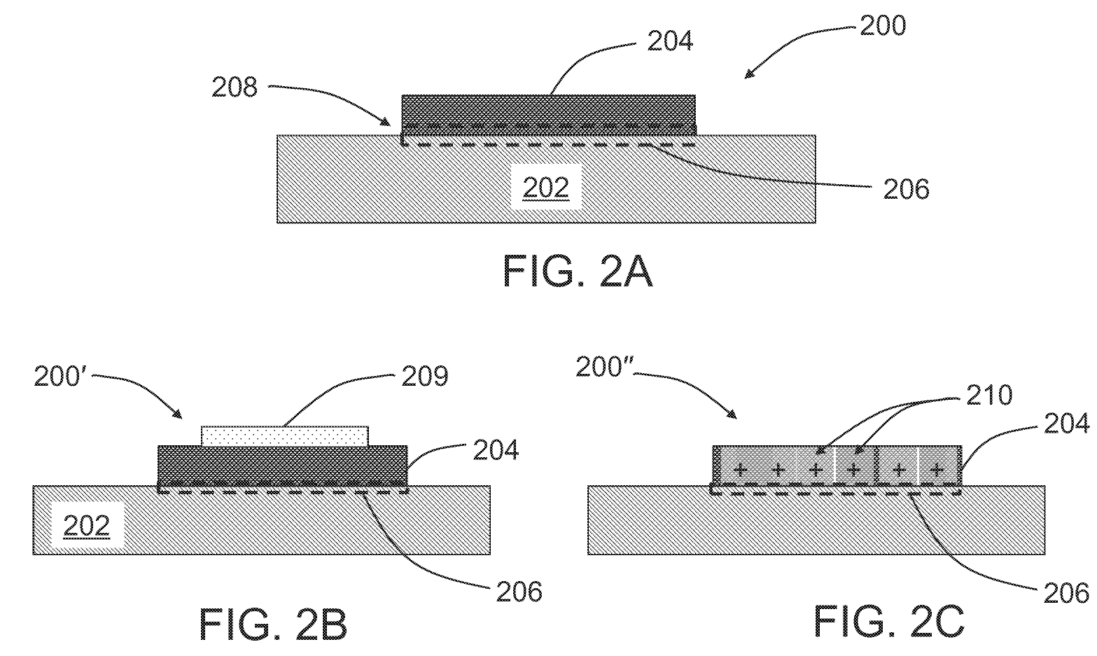

FIG. 2A shows a schematic view of an example semiconductor device 200 based on a graphene-semiconductor heterostructure, according to the principles described herein. The example semiconductor device 200 includes a semiconductor material layer 202 and an electrode 204 formed of a graphene-based material disposed over a portion of the semiconductor material layer to form an overlap region 206. The example semiconductor device also includes a means 208 to provide charge carriers in the graphene-based electrode 204 proximate to overlap region 206, to facilitate the tuning of the work function as described herein.

In an example implementation, the means for providing the charge carriers can include a conductive electrode disposed in electrical communication with the graphene-based electrode. FIG. 2B shows a schematic view of an example semiconductor device 200′ that includes a semiconductor material layer 202, an electrode 204 formed of a graphene-based material disposed over a portion of the semiconductor material layer to form an overlap region 206, and a conductive electrode 209 in electrical communication with the graphene-based electrode 204. According to this example, a potential can be applied to the graphene-based electrode 204 via the conductive electrode 209, to modify the carrier concentration and/or carrier type proximate to the overlap region 206, thereby resulting in the tuning of the work function of the graphene-based material. As described hereinabove, the applied potential can be used to tune the work function of the graphene-based electrode such that it approximates the electron affinity of the semiconductor material layer, thereby resulting in a reduction of the Schottky barrier height.

In another example implementation, the means for providing the charge carriers can include providing an amount of a dopant in at least a portion of the at least one graphene-based electrode. FIG. 2C shows a schematic view of an example semiconductor device 200″ that includes a semiconductor material layer 202, an electrode 204 formed of a graphene-based material disposed over a portion of the semiconductor material layer to form an overlap region 206, where the graphene-based electrode 204 includes an amount of amount of a dopant 210 to provide charge carriers proximate to the overlap region. The example of FIG. 2C illustrates p-type doping of the graphene-based material. As the acceptor dopant concentration increases, the work function of the graphene-based material is increased. In an example with n-type doping of the graphene-based material, as the donor dopant concentration increases, the work function of the graphene-based material is decreased. In this example, the work function of the graphene-based material can be tuned based on the type and/or concentration of the dopant in a portion of the graphene-based electrode, such that the work function approximates the electron affinity of the semiconductor material layer, thereby resulting in a reduction of the Schottky barrier height.

The semiconductor material layer 202 can include many different types of semiconductor material. For example, the semiconductor material layer 202 can include one or more group IV materials, such as but not limited to diamond, silicon, germanium, gray tin, 3C—SiC, 4H—SiC, or 6H—SiC. In another example, the semiconductor material layer 202 can include one or more group VI materials, such as but not limited to sulfur, gray selenium, and tellurium. In another example, the semiconductor material layer 202 can include one or more group III-V materials, such as but not limited to boron nitride, boron phosphide, boron arsenide, aluminum nitride, aluminum phosphide, aluminum arsenide, aluminum antimonide, gallium nitride, gallium phosphide, gallium arsenide, gallium antimonide, indium nitride, indium phosphide, indium arsenide, and indium antimonide. In another example, the semiconductor material layer 202 can include one or more group II-VI materials, such as but not limited to cadmium selenide, cadmium sulfide, cadmium telluride, zinc oxide, zinc selenide, zinc sulfide, and zinc telluride. In another example, the semiconductor material layer 202 can include one or more group I-VII materials, such as but not limited to cuprous chloride, one or more group I-VI materials, such as but not limited to copper sulfide, or one or more group IV-VI materials, such as but not limited to lead selenide, lead sulfide, lead telluride, tin sulfide, tin telluride, lead tin telluride, thallium tin telluride, and thallium germanium telluride. In another example, the semiconductor material layer 202 can include one or more group V-VI materials, such as but not limited to bismuth telluride, or one or more group II-V materials, such as but not limited to cadmium phosphide, cadmium arsenide, cadmium antimonide, zinc phosphide, zinc arsenide, and zinc antimonide.

In other examples, the semiconductor material layer 202 can include one or more oxide materials, such as but not limited to titanium dioxide, silicon oxide, copper oxide, uranium oxide, bismuth oxide, tin dioxide, barium titanate, lithium niobate, and lanthanum copper oxide. In another example, the semiconductor material layer 202 can include one or more layered materials, such as but not limited to lead iodide, molybdenum disulfide, gallium selenide, tin sulfide, and bismuth sulfide. In other examples, the semiconductor material layer 202 can include one or more magnetic materials, such as but not limited to gallium manganese arsenide, indium manganese arsenide, cadmium manganese telluride, lead manganese telluride, lanthanum calcium manganate, iron oxide, nickel oxide, europium oxide, europium sulfide, or chromium bromide.

In other examples, the semiconductor material layer 202 can include one or more transition metal dichalcogenides (TMDCs). The TMDC can be expressed as MX₂, where M is a transition metal (such as but not limited to molybdenum (Mo), tungsten (W), titanium (Ti), tin (Sn), and zirconium), and X is a chalcogen (such as but not limited to sulfur (S) and selenium (Se)). The TDMCs also be fabricated as a single-atom layer material or a multi-layer material.

In other examples, the semiconductor material layer 202 can include a wide bandgap semiconductor material, for applications such as but not limited to high-power electronics, light-emitting diodes, transducers, and high electron mobility transistors. Non-limiting examples of wide bandgap material include, but are not limited to, aluminum nitride, Gallium nitride, boron nitride, diamond, and silicon carbide (SiC).

In another example, the semiconductor material layer 202 can include a homojunction such as a p-n junction. In yet another example, the semiconductor material layer 202 can include a heterojunction, such as but not limited to a p-N junction, a P-n junction, a CdTe/CdS heterojunction, a CdS/CIGS heterojunction, or other types of heterojunctions known in the art.

In another example, the semiconductor material layer 202 can form a portion of a device such as, but not limited to, a transistor, a p-n junction device, a light-emitting diode, a semiconductor laser, a semiconductor detector or sensor, a microprocessor, a solar cell, a bolometer, a laser, a memory, a photovoltaic cell, a gate memory device, a shallow emitter device, and large area radiation detector, or any other known device in the art that includes a metal in contact with a semiconductor material. In non-limiting examples, the transistor can be a bipolar junction transistor, or a field-effect transistor (FET), including a metal-oxide-semiconductor FET (MOSFET), or a junction FET (JFET). The semiconductor material layer 202 can form a portion of the surface of the device, or within the bulk of the device.

In yet another example, the graphene-based electrode and the semiconductor material layer can be formed as a single-atom layer materials, or materials with few layers. As a result, the device can have high flexibility and/or be optical transparent.

In an example, the conductive electrode 209 can be formed from any conductive material, including but not limited to a transition metal (including a refractory metal), a noble metal, a semiconductor, a semimetal, a metal alloy, or other conductive material. In an example, the metal or metal alloy can include but is not limited to aluminum, or a transition metal, including copper, silver, gold, platinum, zinc, nickel, titanium, chromium, or palladium, tungsten, molybdenum, or any combination thereof, and any applicable metal alloy, including alloys with carbon. In an example, the conductive material can be a conductive polymer or a metamaterial. In other non-limiting examples, suitable conductive materials may include a semiconductor-based conductive material, including other silicon-based conductive materials, germanium-based conductive materials, or carbon-based conductive materials, indium-tin-oxide or other transparent conductive oxides, or Group III-IV conductor (including GaAs, InP, and GaN). Other non-limiting examples of III-IV semiconductor systems or semiconductor alloy systems include but are not limited to InAs, InSb, InGaAs, AlGaAs, InGaP, AlinAs, GaAsSb, AlGaP, CdZnTe, AlGaN, or any combination thereof. The semiconductor-based conductive material can be highly doped. In an example, the conductive electrode 209 can include one or more alloy materials, such as but not limited to silicon-germanium, silicon-tin, aluminum gallium arsenide, indium gallium arsenide, indium gallium phosphide, aluminum indium arsenide, aluminum indium antinomide, aluminum arsenide nitride, gallium arsenide phosphide, gallium arsenide antimonide, aluminum gallium nitride, aluminum gallium phosphide, indium gallium nitride, indium arsenide antimonide, indium gallium antimonide, aluminum gallium indium phosphide, aluminum gallium arsenide phosphide, indium gallium arsenide phosphide, indium gallium arsenide antimonide, indium arsenide antimonide phosphide, aluminum indium arsenide phosphide, aluminum gallium arsenide nitride, indium gallium arsenide nitride, indium aluminius arsenide nitride, gallium arsenide antimonide nitride, gallium indium nitride arsenide antimonide, gallium indium arsenide antimonide phosphide, cadmium zinc telluride, mercury cadmium telluride, mercury zinc telluride, mercury zinc selenide, or copper indium gallium selenide.

The graphene-based electrode 204 can include materials other than graphene, such as but not limited to impurities and/or dopants. The impurity may be introduced during the fabrication of the graphene-based material or after the fabrication of the graphene-based material. The graphene-based material can include one or more dopants for adjusting the work function of the graphene-based electrode as described herein. In another example, graphene-based material can include a dopant material for forming a graphene-based composite material such as but not limited to a graphene-based polymer. The graphene-based electrode 204 can include a single layer of graphene (single-atom layer) or multiple layers of graphene.

The graphene-based material can be fabricated by a number of techniques in the art. The different fabrication methods can result in different types of graphene-based material in terms of number of layers, uniformity of the layers, number of possible defects, and amount or type of impurities in the produced graphene-based material. In one example, the graphene-based material is produced by mechanical exfoliation, in which the graphene-based material can be extracted from a graphite crystal using an adhesive, including using an adhesive tape. After separating the adhesive material from the graphite crystal, e.g., by peeling, a multi-layer graphene-based material can be retained on a portion of the adhesive material, e.g., on the surface of the adhesive tape. Repeated separation of the multi-layer graphene-based material can reduce the number of layers in the multi-layer graphene, until a few as a single layer remains (e.g., on the tape). Then the adhesive can be contacted to a substrate, and the adhesive can be solved, for example, using acetone, to leave behind the multi-layered or single-atom-layered graphene-based material on the substrate.

In another example, the graphene-based material can be fabricated using a liquid phase exfoliation, in which a graphite crystal can be exposed to a solution with similar surface energy as graphite, so as to facilitate the overcoming of energy barriers to detach a graphene-based material layer from the crystal. An ultrasound wave can be applied to the solution to speed up the exfoliation. The solution can be, for example, a mixture of dilute organic acid, alcohol, and water. In operation, the acid works as a “molecular wedge” which separates sheets of graphene-based material from the parent graphite. By this simple process, a large quantity of undamaged, high-quality graphene-based material dispersed in water can be created.

In yet another example, the graphene-based material can be fabricated through growth on the surface of a SiC crystal. Heating and cooling the SiC crystal can result in generation of a thin film of graphene-based material on the surface. A single-layered or bi-layered graphene-based material can be formed on the Si face of the crystal, whereas a multi-layered graphene-based material can be grown on the C face. By tuning parameters such as temperature, heating rate, or pressure, graphene-based materials of different sizes and thickness can be produced.

In yet another example, the graphene-based material can be fabricated using chemical vapor deposition (CVD). The CVD process can include exposing a substrate to gaseous compounds that can be caused to decompose on the substrate surface to form a thin film. For example, the graphene-based material can be grown by exposing a metal foil to a gas mixture of H₂, CH₄, and Ar at about 1000° C. The methane can decompose on the surface, releasing carbon that can diffuse into the metal foil. The foil is cooled in an Ar atmosphere, with a graphene-based material layer being formed on the metal surface. Usually, the metal foil can be selected from nickel or copper, and different thickness of the metal foil may result in graphene-based material of different numbers of layers. In addition, patterning the metal foil (e.g., coating) can produce graphene-based material of in desired shapes.

In yet another example, the graphene-based material can be fabricated using a 3D printing technique. For example, the graphene can be fabricated as flakes that may be configured for deposition using a 3D printing method to fabricate the graphene-based electrodes or other components of the example devices described herein.

The graphene-based electrode 204 can be fabricated in various shapes, depending on the configuration of the resulting device. For example, the graphene-based electrode 204 can be fabricated in a rectangular, square, round oval, polygonal, narrow strips, arrays of strips, grid, frame, or serpentine shape, or any combination of one or more shapes. In one example, the graphene-based electrode 204 can be pre-fabricated in the desired shapes and then disposed over the semiconductor material layer 202. For example, the patterned graphene-based material can be created on a patterned nickel or copper foil, and then transferred to the semiconductor material layer 202 via a polymer support. In another example, a uniform sheet of graphene-based material can be disposed over the semiconductor material layer 202, and then fabricated to the desired shape by selective removal of a portion of the graphene-based material sheet via, for example, electron beam lithography or etching.

As described in connection with FIG. 2C, the graphene-based electrode 204 can be doped with an amount of an acceptor dopant or a donor dopant to provide charge carriers, so as to tune the work function of the graphene-based electrode 204. The doping of the graphene-based electrode 204 can be performed either during the fabrication (or synthesis) of the graphene-based material, or using a post treatment technique (i.e., after the preparation of the graphene-based material).

Non-limiting examples of post treatment technique applicable to the systems, apparatus, and methods described herein include electrostatic doping, a plasma treatment, an oxide deposition, a molecule deposition, a gas phase annealing technique, substrate engineering, dipping, or coating in a wet chemical. The wet chemical can be an acid, a base, a metal chloride, or an organic material.

In one example, the work function of the graphene-based electrode 204 can be adjusted before, during, or after operation of the device. For example, the operation of the device 200 may involve exposure to irradiation (e.g., electromagnetic or particle irradiation), to alter the properties of the semiconductor material layer 202 and result in a change of the electron affinity of the semiconductor material layer 202. This allows the tuning of work function to match the altered electron affinity of the semiconductor material layer 202.

In another example, the device 200 can be configured for compactness, such as but not limited to in highly integrated flexible electronics, including in devices to be implanted.

In an example method, hetero-atoms (i.e., atoms other than carbon) can be introduced into the graphene-based electrode 204 to regulate (including to control) the work function of the graphene-based electrode 204. The hetero-atoms can be boron or nitrogen, due to their similarity in atomic size to carbon. The boron can be used as an acceptor dopant (substitutional B-doping), while the nitrogen can be used as a donor dopant (substitutional N-doping).

The hetero-atoms can be introduced into the graphene-based material in several ways. In one example, an arc discharge method can be employed to prepare the B- and/or N-doped graphene-based material via a high-current between graphite electrodes in the presence of H₂+B₂H₆ and H₂+NH₃, respectively.

In another example, the graphene-based material can be N-doped as a part of the CVD process. The CVD process for the graphene-based material doping can be carried out as follows: (I) at high temperature (e.g., >800° C.) a catalyst (transition metals) is liquidized, acting as the catalytic sites for absorption and dissociation of the gas reactants including N-containing reactant (e.g., NH₃); (II) the catalyst becomes saturated with the atoms/fragments from the dissociation of the reactants; and (III) solid graphitic carbon (graphene layers) grows from the saturated catalyst by means of precipitation, with the adsorbed N− atoms precipitating into the graphitic lattice, giving rise to a N-doped carbon material. In one example, a copper film on a silicon substrate is used as the catalyst under a H₂ atmosphere (which can be mixed with Argon). A mixture of CH₄ and NH₃ can be used as the carbon and nitrogen source.

In yet another example, N-doped graphene-based material can be fabricated through electro-thermal reactions with NH₃. In yet another example, N⁺ ion or plasma irradiation followed by NH₃ annealing can be employed to introduce nitrogen atoms into the graphene-based material. In this example, defects can be formed in the plane of pristine graphene from ion irradiation. Raman spectroscopy can be employed to monitor the amount of defects. During the subsequent annealing step in NH₃, the defects can be restored by filling nitrogen atoms into the carbon vacancies, therefore producing N-doped graphene. The doping concentration can be controlled by tuning the specific conditions of irradiation and annealing, and it is also possible to replace the N atoms with other dopants.

In another example method, the graphene-based material can be chemically treated to adjust the work function. Without being bound by any theory or mode of operation, chemical modification can be effective in work function tuning of graphene-based material due to the two-dimensional nature of graphene, which has only one layer of atoms and an absolute maximum of the surface area to volume ratio. The graphene-based material can be sensitive to atomic or molecular modification, in which molecules of either hole (acceptor) or electron (donor) dopants can lead to p- or n-type characters, respectively.

Similar to hetero-atom doping, chemical modification of graphene-based material can also be achieved in several ways. In one example, non-aromatic or aromatic molecules can be used to control the doping of the graphene-based material. For example, tetrafluorotetracyanoquinodimethane (F4-TCNQ), an acceptor (hole donor), can be used to tune the Fermi level of the graphene-based material through non-covalent functionalization. Aromatic molecules can be used to modulate the electronic structures of the graphene-based material via strong π-π interaction between their aromatic rings and graphene. Aromatic molecules with electron-donor groups (e.g., 9,10-Dimethylanthracene (An-CH3), 1,5-Naphthalenediamine (Na-NH2)) can be used for n-type doping, while those with acceptor (hole donor) groups can be used for p-type doping (e.g., 9,10-Dibromo-anthracene (An-Br), tetrasodium 1,3,6,8-pyrenetetrasulfonic acid (TPA)) of the graphene-based material.

In another example, an electrochemical solution can be used to treat the graphene-based material and induce work function alteration. In this example, the graphene-based material can be exposed to an ionic liquid, and a conductive electrode can be provided in electrical contact with the graphene-based material. Applying a voltage between the ionic liquid and the graphene-based material, via the conductive electrode can drive charge carriers into the graphene-based material, thereby resulting in the tuning of the work function as described hereinabove. The ionic liquid can be, but Is not limited to, H₂SO₄, HCl, HNO₃, AuCl₃, FeCl₃, MoCl₂, PdCl₂, N-phenyl-bis(trifluoromethane sulfonyl)imide (PTFSI), silver bis(trifluoromethane sulfonyl)imide (STFSI), bis(trifluoromethane sulfonyl)amine, 1,5-naphthalenediamine (Na-NH2), 9,10-dimethylanthracene (An-CH3), 9,10-dibromoanthracene (An-Br), and tetrasodium 1,3,6,8-pyrenetetrasulfonic acid (TPA), hydrazine (N₂H₄), or any other ionic liquids known in the art.

In yet another example method, the work function of the graphene-based material can be tuned via an electrostatic method, in which reversible changes of carrier concentration and the Fermi level can be controlled by an electrostatic field applied to the graphene-based electrode. As a non-limiting example, top-gate and back-gate transistors (such as field-effect transistors) can be used for electrostatic field tuning, in which the Fermi level of a graphene-based material can be finely tuned from conduction band to valence band, following the change of the gate voltage from negative to positive, corresponding to the p-type and n-type graphene-based material. The graphene-based material to be tuned can be placed over a SiO2/p⁻⁺Si substrate, and the top-electrode (top-gate) can be provided in the n-doped area, while the back-gate can be provided in the p-doped region.

In yet another example method, the work function of the graphene-based material can be tuned using an electric field applied over the graphene-based material through a dielectric material. In this example, an electrode can be disposed over the dielectric material, which is disposed over the graphene-based material. The voltage can be applied across the dielectric to drive charge carriers into the graphene-based material, thereby tuning the work function of the graphene-based material as described herein. Candidate dielectric materials include, but are not limited to, MoO₃, ReO₃, Rb₂CO₃, Cs₂CO₃, silicon dioxide, tantalum oxide, and aluminum oxide.

In yet another example, the work function of the graphene-based material can be altered via photo-induced doping. In this example, the graphene-based electrode 204 can be coupled to a substrate having defect states in the bulk of the substrate (e.g., where the substrate is boron nitride), or a substrate including interfacial charge traps in an amorphous oxide (e.g., where the substrate is silicon oxide). The substrate and graphene-based material can be exposed to electromagnetic radiation, such as but not limited to incandescent light, while a sweeping voltage is applied to the graphene-substrate heterostructure. The induced modulation doping can arise from defect states in the bulk of the substrate, or from interfacial charge traps in the amorphous oxide. The photo-induced doping can last for a period of time (e.g., for days) if the device is maintained in a dark environment. Alternatively, the photo-induced doping can be erased by exposing the substrate and graphene-based material to electromagnetic radiation with zero applied voltage. The erasure procedure may take a higher dosage of light than the doping procedure.

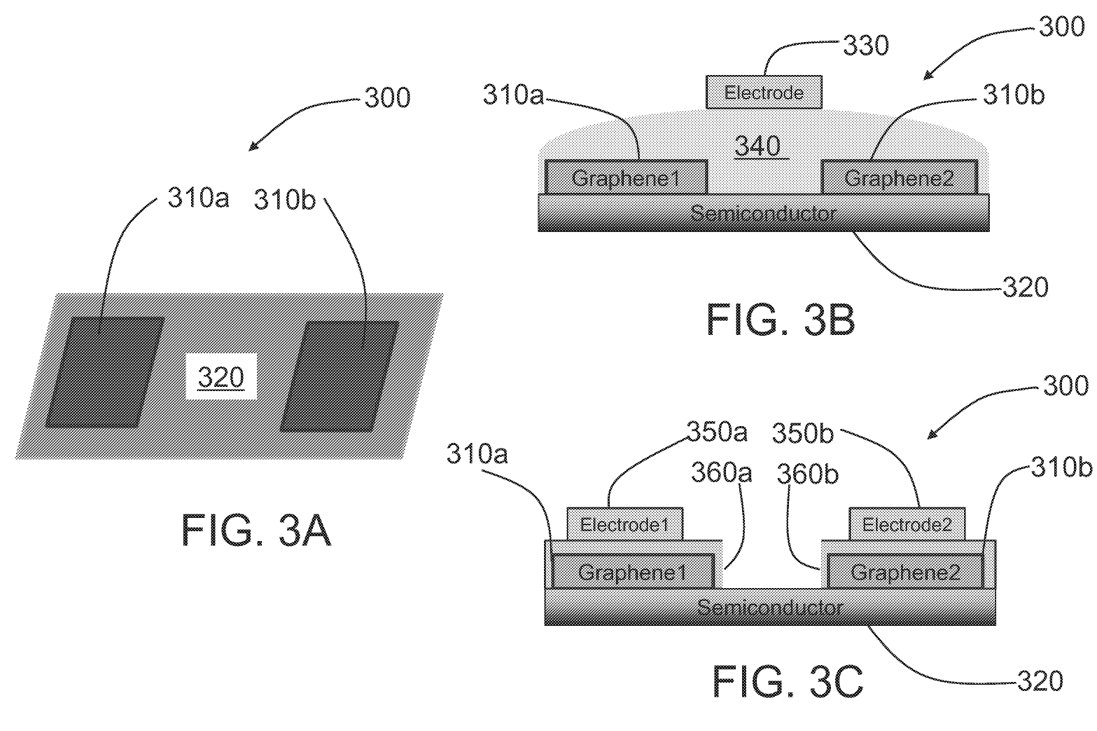

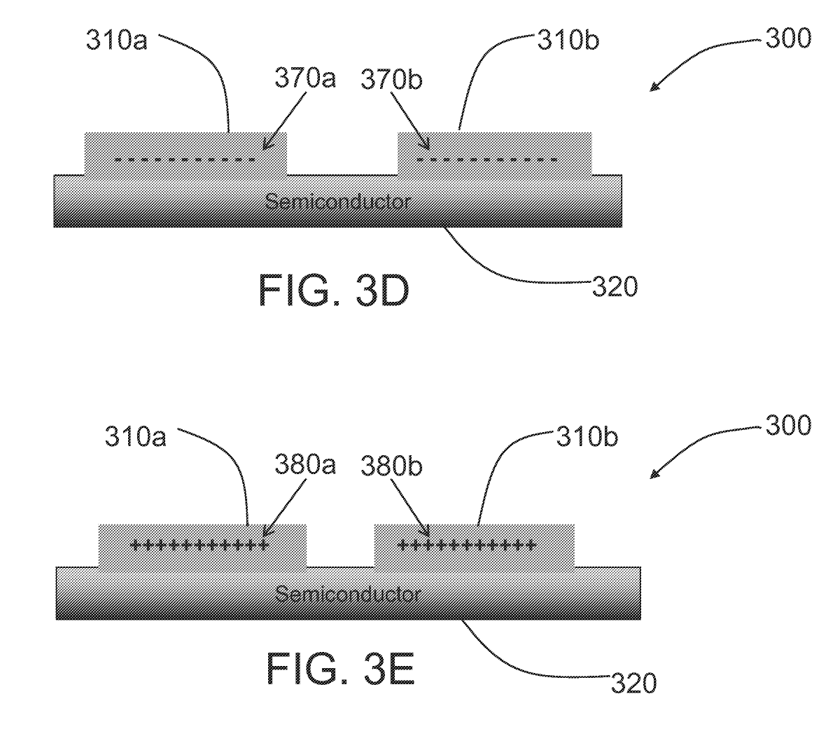

FIG. 3A which shows a top view of an example semiconductor device 300 that includes a pair of graphene-based electrodes 310a and 310b (also collectively referred to as graphene-based electrodes 310) disposed over a semiconductor layer 320. Non-limiting example variations in the example semiconductor device 300 are shown in FIGS. 3B-3D. The components of FIGS. 3A-3E can be formed from any of the materials described herein in connection with equivalent components of the example structure of FIGS. 2A, 2B and/or 2C.

The graphene-based electrodes 310a and 310b and the semiconductor layer 320 in the example semiconductor device 300 can be formed from any of the materials described herein in connection with equivalent components of the example structure of FIGS. 2A, 2B and/or 2C.

FIG. 3B shows a cross-sectional view of an example of the semiconductor device 300 that includes the graphene-based electrodes 310a and 310b are disposed over the semiconductor layer 320. Each one of the graphene-based electrodes 310a and 310b disposed over and firming an overlap region with the semiconductor layer 320. An ionic liquid (IL) 340 is disposed over the graphene-based electrodes 310a and 310b. The ionic liquid (IL) 340 can be a liquid electrolyte, an ionic melt, an ionic fluid, a fused salt, a liquid salt, or an ionic glass. For example, the ionic liquid 340 can be a salt in a liquid state, and can include ions and short-lived ion pairs. The example semiconductor device 300 also includes a conductive electrode 330 that is in electrical communication with the ionic liquid 340. The conductive electrode 330 can be used to apply a voltage between the ionic liquid 340 and the graphene-based electrodes 310a and 310b, or to apply an electric field across the interface between the ionic liquid 340 and the graphene-based electrodes 310a and 310b. That is, the conductive electrode is in electrical communication with the graphene-based electrodes via the ionic liquid. Under the electrical force, charge carriers (e.g., ions or ion-pairs) in the ionic liquid can be moved towards the graphene-based electrodes 310a and 310b, thereby tuning the work function of the graphene-based electrodes 310a and 310b. The work function can be tuned to approximate the electron affinity of the semiconductor layer 320 and substantially reduce the Schottky barrier height at the graphene-semiconductor interface. As described before, a reduced Schottky barrier height can facilitate charge transfer across the graphene-semiconductor interface, thereby improving the performance of the semiconductor device 300.

The conductive electrode 330 can be disposed over the ionic liquid 340 (as shown in FIG. 3B), or on the side of the ionic liquid 340, or can be at least partially embedded the ionic liquid 340. A positive or negative voltage can be applied to the conductive electrode 330 depending on, for example, the type of charge carriers in the ionic liquid 340. For example, if the charge carriers are positive ions in the ionic liquid 340, then it can be more desirable to apply a positive voltage on the conductive electrode 330 in order to drive the positive charge carriers or dopants into the graphene-based electrode 310. In this example, the graphene-based electrodes 310a and 310b, or the semiconductor layer 320 can be held at ground.

The conductive electrode 330 can be formed from a conductive metal, a conductive metal oxide, a conductive polymer, carbon, or other conductive material (including any conductive material described herein) that facilitates application of a voltage or an electric field to the graphene-based electrodes 310a and 310b. In one example, the conductive electrode 330 can be based on gold, platinum copper, tantalum, tin, tungsten, titanium, tungsten, cobalt, chromium, silver, nickel or aluminum, or a binary or ternary system of any of these conductive materials. In another example, the conductive electrode 330 can include a similar graphene-based material as the two graphene-based electrodes 310a and 310b. While FIG. 3B shows a single conductive electrode 330, example semiconductor device 300 can include more than one conductive electrode 330. For example, example semiconductor device 300 can include two conductive electrodes 330 operably coupled to the ionic liquid 340, operably coupled to apply a voltage to the pair of graphene-based electrodes 310a and 310b.

The ionic liquid 340 can be one or more of H₂SO₄, HCl, HNO₃, AuCl₃, FeCl₃, MoCl₂, PdCl₂, N-phenyl-bis(trifluoromethane sulfonyl)imide (PTFSI), silver bis(trifluoromethane sulfonyl)imide (STFSI), bis(trifluoromethane sulfonyl)amine, 1,5-naphthalenediamine (Na-NH2), 9,10-dimethylanthracene (An-CH3), 9,10-dibromoanthracene (An-Br), and tetrasodium 1,3,6,8-pyrenetetrasulfonic acid (TPA), hydrazine (N₂H₄), or any other ionic liquids known in the art.

In the example of FIG. 3B, the ionic liquid 340 is shown as being in contact with the semiconductor layer 320. However, in other examples, another material may be disposed between the ionic liquid 340 to separate it from the semiconductor layer 320. For example, a passivation layer, diffusion battier, or other dielectric material may be disposed between the ionic liquid 340 and the semiconductor material layer 320.

FIG. 3C shows a side view of a semiconductor device 300 according to another exemplary embodiment. The semiconductor device 300 includes a pair of graphene-based electrodes 310a and 310b disposed over a semiconductor layer 320, a pair of dielectric layer 360a and 360b (collectively referred to dielectric layers 360) disposed over the graphene-based electrodes 310a and 310b, and a pair of conductive electrodes 350a and 350b (collectively referred to as conductive electrodes 350) operably coupled to the dielectric layers 360, with conductive electrode 350a coupled to dielectric layer 360a, and conductive electrode 350b coupled to dielectric layer 360b.

The graphene-based electrodes 310a and 310b, the semiconductor layer 320, and the conductive electrodes 350a and 350b of FIG. 3C can be formed from any of the materials described herein in connection with equivalent components of the example structure of FIGS. 2A, 2B and/or 2C. The dielectric layers 360a and 360b can include, for example, one or more of MoO₃, ReO₃, Rb₂CO₃, Cs₂CO₃, potassium, and aluminum oxide, or any other dielectric material described herein. The two dielectric layers 360a and 360b can be either formed from the same material or different materials. In one example, the dielectric layers 360a and 360b can be conformally coupled to the graphene-based electrodes 310a and 310b. For example, the dielectric layers can be fabricated to cover both the top and sides of the graphene-based electrodes 310a and 310b. In another example, the dielectric layers 360a and 360b may be coupled to only a portion (e.g., the top surface) of the graphene-based electrodes 310a and 310b.

The thickness of the dielectric layers 360a and 360b can be determined based on, for example, the designated voltage to be applied on the conductive electrodes 360a and 350b, the desired doping concentration, the desired overall thickness of the device 300, the flexibility (or pliability) of the device 300, and/or the fabrication constraints. In operation, a voltage can be applied to the conductive electrodes 350a and 350b with respect to the graphene-based electrodes 310a and 310b so as to drive charge carriers into the graphene-based electrodes 310a and 310b. Therefore, the thickness of the dielectric layer 360 may be determined by taking into at least two considerations. On the one hand, it can be beneficial for the dielectric layers 360a and 360b to have a thickness that can prevent discharge (short circuit) inside the dielectric layers 360a and 360b. On the other hand, it can also be desirable to control the total thickness (or other dimensions) of the resulting device 300 so as to fit the dimensional constraints specific applications that might have limited available space. A practical range of the thickness can be, for example, about 100 nm to about 10 μm, or about 500 nm to about 5 μm, or about 1 μm to about 3 μm.

FIGS. 3D and 3E show example semiconductor devices 300, in which the means for providing charge carriers in the graphene-based electrodes is via doping. FIG. 3D shows an example device 300 that includes a pair of graphene-based electrodes 310a and 310b disposed over a semiconductor layer 320. The graphene-based electrodes 310a and 310b are doped with negative charge carriers 370a and 370b (collectively referred to as negative charge carriers 370). FIG. 3E shows an example device 300 in which the graphene-based electrodes 310a and 310b are doped with positive charge carriers 380a and 380b (collectively referred to as 380).

The charge carriers, whether from acceptor dopants or donor dopants, can be configured to have different types of distributions in the graphene-based electrodes 310a and 310b. In one example, the charge carriers can be uniformly distributed across a depth of the graphene-based electrode. In another example, the charge carriers can be more concentrated at the graphene-semiconductor interface. In yet another example, when the graphene-based electrodes 310a and 310b include only a single layer of the graphene-based material, the doped charge carriers can be embedded in portions of the lattices of the graphene material. The dopant charge concentration can be from varied from substantially zero to about 50×10¹² cm⁻² or more, depending on the target work function desired.

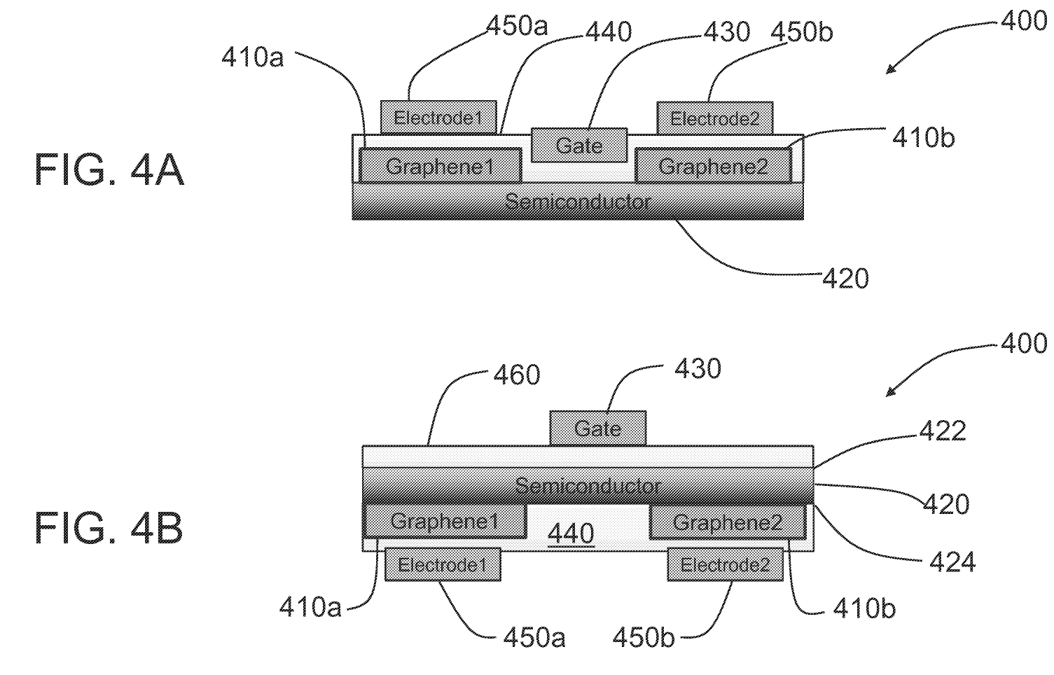

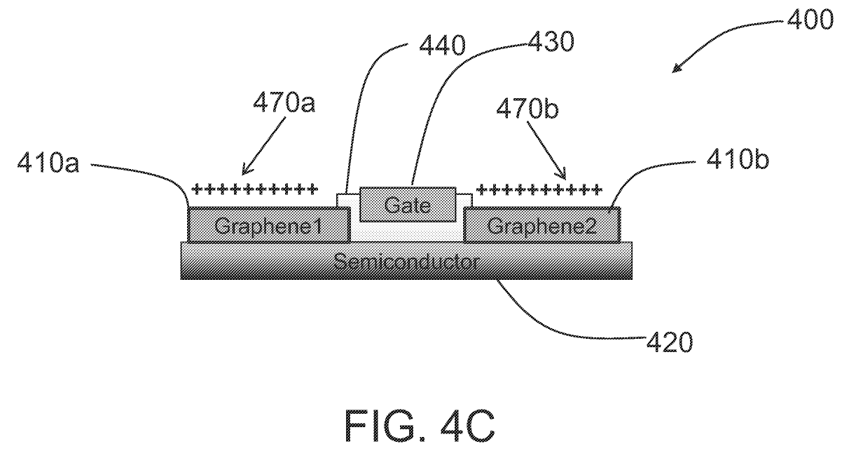

FIG. 4A-4C show example devices 400 that are configured as transistor structures. FIG. 4A shows an example device 400 that includes a pair of graphene-based electrodes 410a and 410b (collectively referred to as graphene-based electrodes 410) disposed over a semiconductor device 420, a dielectric layer 440, a gate electrode 430, and a pair of conductive electrodes 450a and 450b (collectively referred to as conductive electrodes 450). The dielectric layer 440 is disposed over the graphene-based electrodes 410. The gate electrode 430 is disposed over the dielectric layer 440, above a region of the semiconductor layer 410 that is between the two graphene-based electrodes 410a and 410b. The conductive electrodes 450a and 450b are disposed over the dielectric layer 440, each disposed over a graphene-based electrode 410a and 410b.

As a non-limiting example, example device 400 can be a metal-oxide-semiconductor field-effect transistor (MOSFET).

The components of FIGS. 4A-4C can be formed from any of the materials described herein in connection with equivalent components of the example structure of FIGS. 2A, 2B and/or 2C.

In operation, the graphene-based electrodes 410a and 410b can function as source and drain electrodes, while the gate electrode 430 can be used to adjust a channel depth (or width) of the semiconductor layer 420, such that the example device 400 functions as a transistor. The conductive electrodes 450a and 450b can be used to apply an electric field over the graphene-based electrodes 410 to tune the work function of the graphene-based electrodes 410a and 410b. As a result, the work function of the graphene-based electrodes 410a and 410b can be tuned to approximate the electron affinity of the semiconductor layer 420, therefore reducing or eliminating the Schottky barrier height and facilitating charge transfer.

The example device 400 can be configured such that the gate electrode 430 and the conductive electrodes 450 are disposed above the dielectric layer 440 (as shown in FIG. 4A), or are at least partially embedded in a portion of the dielectric layer 440, and electrically coupled to external voltage source through wires (not shown). In some applications, burying one or more of the electrodes inside the dielectric layer 440 may help protect the electrodes from corrosion or damage from the operation of the device 400.

As shown in the example of FIG. 4A, two conductive electrodes 450a and 450b can be used, where each conductive electrodes 450a and 450b is used to adjust the work function of one of the graphene-based electrode 410. For example, a potential applied to conductive electrode 450a can be used to adjust the work function of graphene-based electrode 410a; and a potential applied to conductive electrode 450b can be used to adjust the work function of graphene-based electrode 410b. The voltage applied to conductive electrode 450b can be the same as, or different from, the voltage applied to conductive electrode 450b. These voltages can be applied using a single source, or using separate sources such that each graphene-based electrode can be independently tuned. In another example, a single conductive electrode (450a or 450b) can be used to adjust both graphene-based electrodes 410a and 410b. For example, the device 400 can be configured with a single “U” shaped conductive electrode 450 with the two legs disposed substantially in electrical communication with the two graphene-based electrodes 410a and 410b.

FIG. 4B shows a cross-sectional view of an example device 400 where the gate electrode 430 and the conductive electrodes 450a and 450b are disposed on opposite sides of semiconductor material layer 420. A dielectric layer 460 is disposed on the surface 422 of the semiconductor layer 420. A gate electrode 430 is disposed above the dielectric layer 460. A pair of graphene-based electrodes 410a and 410b (collectively referred to as graphene-based electrodes 410), a dielectric layer 440, and a pair of conductive electrodes 450a and 450b (collectively referred to as conductive electrodes 450), are disposed on the surface 424 of the semiconductor layer 420. The dielectric layer 440 covers at least a portion of the surface of the graphene-based electrodes 410 such that an electric field can be applied across the dielectric layer 440 toward the or from the graphene-based electrodes 410, so as to tune the work function of the graphene-based electrodes 410a and 410b.

In operation, the gate electrode 430 can be used to apply a voltage across the dielectric layer 460 with respect to the surface 422 of the semiconductor layer 420 to adjust a channel depth or width of the semiconductor layer 420. The two graphene-based electrodes 410a and 410b can be used to function as the source and drain electrodes, such that the device 400 can function as a transistor.

The front dielectric layer 460, in various example implementations, can include an inorganic dielectric material that includes an oxide or a nitride of aluminum, silicon, germanium, gallium, indium, tin, antimony, tellurium, bismuth, titanium, vanadium, chromium, manganese, cobalt, nickel, copper, zinc, zirconium, niobium, molybdenum, palladium, cadmium, hafnium, tantalum, or tungsten, or any combination thereof. In another example implementation, the front dielectric layer 460 can include an inorganic dielectric material that includes aluminum oxide, bismuth zinc niobate, hafnium oxide, barium strontium titanate, silicon nitride, or any combination thereof.

FIG. 4C show an example device 400 where the means for providing the charge carriers is through doping the graphene-based electrodes. Example device 400 includes a pair of graphene-based electrodes 410a and 410b disposed over a semiconductor layer 420, and a dielectric layer 440 disposed between the semiconductor layer 420, and a gate electrode 430. In this example, the graphene-based electrodes 410a and 410b are doped with positive charge carriers 470a and 470b. In another example, graphene-based electrodes 410a and 410b can be doped with negative charge carriers.

The dielectric layer 440 of the example device 400 shown in FIG. 4C covers a portion of the graphene-based electrodes 410a and 410b, to electrically separate the gate electrode 430 and the semiconductor layer 420 such that a potential can be applied across them. In another word, the dielectric layer 440 can prevent discharge or a short circuit. In some example implementations, the dielectric layer 440 can be separated from the graphene-based electrodes 410a and 410b. In some other example implementations, the dielectric layer 440 can substantially cover the graphene-based electrodes 410a and 410b (e.g., for passivation, protection or sealing).

In any example herein, the gate electrode (including gate electrode 430) of a transistor or other semiconductor device can be formed from a graphene-based material, or any of the conductive materials described herein in connection with a conductive electrode. In an example, the gate electrode (including gate electrode 430) can be formed from a graphene-based material in electrical communication with a conductive electrode, where a voltage can be applied to the conductive electrode can be used to tune a Schottky barrier height (as described herein) between the graphene-based gate electrode and the semiconductor material layer of the transistor or other semiconductor device. In another example, the gate electrode (including gate electrode 430) can be formed from a graphene-based material that is doped with an amount of a dopant to provide charge carriers to tune a Schottky barrier height (as described herein) between the graphene-based gate electrode and the semiconductor material layer of the transistor or other semiconductor device.

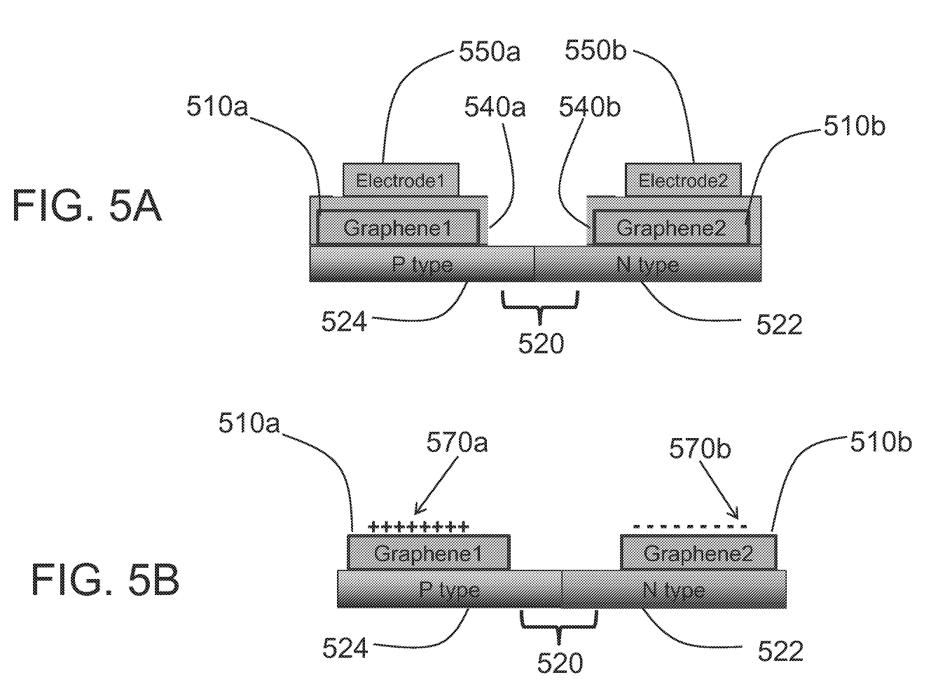

FIGS. 5A and 5B show example devices where the semiconductor material layer includes a p-n junction. The components of FIGS. 4A-4C can be formed from any of the materials described herein in connection with equivalent components of the example structure of FIGS. 2A, 2B and/or 2C.

In FIG. 5A, the semiconductor material layer 520 of the example device 500 includes a N-type region 522 and a P-type region 524, and the means for providing the charge carriers to the graphene-based electrodes includes using conductive electrodes to apply a voltage to tune the respective work function. A graphene-based electrode 510a, dielectric layer 540a, and a conductive electrode 550a are disposed over the P-type region 524. Conductive electrode 550a is operably coupled to the dielectric layer 540a. A graphene-based electrode 510b, dielectric layer 540b, and conductive electrode 550b are disposed over the N-type region 522. Conductive electrode 550b is operably coupled to the dielectric layer 540b.

In operation, voltages of different signs can be applied on the conductive electrodes 550a and 550b. As a non-limiting example, a positive voltage can be applied to the conductive electrode 550a and a negative voltage can be applied to the conductive electrode 550b. The magnitude of the voltage applied using 550a or 550b would be selected to tune the work function of each graphene-based electrode 510a and 510b to reduce the Schottky barrier height at each respective interface. The voltages applied to the conductive electrodes 550a and 550b can be delivered using separate voltage sources such that each graphene-based electrode can be independently tuned. As non-limiting example, the voltage applied to the conductive electrodes 550a or 550b can range from about −70 volts to about +70 volts.

In FIG. 5B, the semiconductor material layer 520 of the example device 500 includes a N-type region 522 and a P-type region 524, and the means for providing the charge carriers involves doping of the graphene-based electrodes to tune the respective work function. The graphene-based electrode 510a over the P-type region 524 is doped with positive charge carriers, and the graphene-based electrode 510b over the N-type region 522 is doped with negative charge carriers. As a non-limiting example, the doped charge carriers, either positive or negative or both, can be substantially concentrated close to the graphene-based material surface, within the bulk of the graphene-based material (if multiple layers are used), or close to the graphene-semiconductor interface.

Some examples herein are described relative to using as a means for providing the charge carriers either (a) applying a voltage using a conductive electrode disposed in electrical communication with a graphene-based electrode, or (b) an amount of a dopant provided in at least a portion of the at least one graphene-based electrode, for tuning the work function of the graphene-based electrode.

In other examples, the systems, apparatus, and methods can implement both (a) a conductive electrode disposed in electrical communication with a graphene-based electrode, and (b) an amount of a dopant provided in at least a portion of the at least one graphene-based electrode, for tuning the work function of the graphene-based electrode. For example, an example herein for doping the graphene-based electrodes can be implemented before, during, or after fabrication of the device, to tune the work function of at least one of the graphene-based electrodes. In addition, at least one conductive electrode also can be disposed in electrical communication with at least one of the graphene-based electrodes, to apply a voltage for additional tuning (including finer tuning) of the work function of at least one of the graphene-based electrodes to further reduce the Schottky barrier height and improve the performance of the device.

According to the principles described herein, two-dimensional (2D) materials can be promising for extending electronics into new application domains. The atomic organization and bond strength within the plane of a two dimensional structure can be stronger than along the third dimension. In 2D materials, charge and heat transport can be confined to a plane, leading to many unique properties. For example, 2D materials can be configured to exhibit excellent mechanical flexibility and transport properties, facilitating electronic systems that can be made bendable, transparent and can be placed onto a wide variety of surfaces. In another example, 2D materials with layered metal dichalcogenides (LMDCs), copper oxides, and iron p nitrides can exhibit correlated electronic phenomenon such as charge density waves and high-temperature superconductivity.

Example 2D materials herein can include a single-atom-thick or a single-polyhedral-thick layer of materials such that the atomic organization or bond strength can be substantially within the layer. The single-atom or single-polyhedral nature of 2D materials also results in small thickness (normally on the order of nanometers), which can make 2D materials lightweight, bendable, rollable, portable, and potentially foldable.

Three classes of materials that can be prepared as single-atom or single-polyhedral-thick layer are described.

The first class of materials that can be reduced to stable single-atom or single-polyhedral layers are layered van der Waals solids. These crystal structures have neutral, single-atom-thick or single-polyhedral-sick layers of atom that are covalently or ionically connected with their neighbors within each layer, whereas different layers are held together via van der Waals bonding along the third axis. Since van der Waals bonding is typically weak (around 40-70 meV), single-atom layers can be achieved by exfoliation, including mechanical exfoliation, chemical exfoliation, and atom/molecule intercalation, among others.

For example, bulk graphite can be mechanically exfoliated using an adhesive (such as but not limited to adhesive tape), and the resulting single-atom layer graphene can exhibit good electrical and thermal conductivities. In another example, atomically thin layers of transition metal dichalcogenides (TDMC) MX₂ can be achieved by exfoliating the corresponding bulk crystals, where M can be Mo, Ti, Zr, Hf, V, Nb, Ta, or Re, among others, and X can be S, Se, or Te, among others. The resulting 2D TDMC can have semiconducting properties and can replace or supplement existing semiconducting materials such as silicon.

The second class of materials that can have stable single atom layers are layered ionic solids, which are bulk crystals with charged 2D polyhedral layers, typically held together with electropositive cations or electronegative anions. These cations and/or anions can be exchanged with bulk organic cations and/or anions, such as tetrabutylammonium or dodecyl sulfate, to achieve dispersion as single layers in solution. These materials can then be dispersed onto substrates, with the majority of materials depositing as single to few layers. Layered ionic solids include, but are not limited to, cation-exchanged layers from Ruddlesden-Popper perovskite-type structures, such as KLn₂Ti₃O₁₀, KLnNb₂O₇, RbLnTa₂O₇, and KCa₂Nb₃O₁₀ (Ln=lanthanide ion), cation-exchanged layered metal oxides, such as LiCoO₂ and Na₂Ti₃O₇, and halide- or hydroxide-exchanged layers derived from metal hydroxides, such as Ni(OH)₂-x or Eu(OH)_{2.5}Cl_{0.5}.

The third class of single-atom layers can be materials deposited on substrates, offering the potential to grow and study the properties of 2D materials beyond those existing as layered bulk crystals (e.g., layered van der Waals and ionic solids). The deposition can be, for example, solution-phase growth or vapor deposition. Solution-phase growth can include solvothermal or colloidal growth reaction. For example, LMDCs such as TiS₂, VS₂, ZrS₂, HfS₂, TaS₂, TiSe₂, VSe₂ and NbSe₂ can be prepared by general colloidal synthetic methods, via the reaction of metal halides and carbon sulfide or elemental selenium in the presence of primary amines. Vapor deposition methods can include chemical vapor deposition (CVD) and low pressure chemical vapor deposition (LPCVD). For example, single layer graphene can be achieved by LPCVD on copper foil substrates using methane as a carbon source. Other layered systems that can be achieved by vapor deposition include hexagonal boron nitride (h-BN) and MoS₂, which compose two or more elements.

An electronic system, including flexible electronic systems, can include functional components (e.g., transistors, logic gates, etc.), contacts (e.g., electrodes) and interconnects (e.g., wires). To harvest the full advantages of 2D electronics, it can be helpful to construct systems based on 2D materials and their heterostructures, i.e., fabricating several components in the electronic system using 2D materials. So far, however, circuits that have been constructed based on 2D materials can rely on metal (e.g., titanium or indium tin oxide) to fabricate contacts and interconnects, which can raise several potential issues. The metal-semiconductor interface can present the Schottky barrier (the potential energy barrier as described herein), which can be induced by the mismatch between the work function of the metal material and the electron affinity of the semiconductor material. In operation, Schottky barriers can block charge flow across the metal-semiconductor interface, therefore imposing limitations on performance of the semiconductor devices and the electronic systems based on them. Furthermore, crack formation at the interface between metal contacts and interconnects can limit the performance of flexible electronics, limiting their robustness to repetitive bending and stretching. Moreover, commonly used sputtering process used in the fabrication of metal electrodes may potentially damage the 2D materials used for other components in the system.

Use of the graphene-based electrodes as the contact materials, instead of or in addition to metals or metal oxides, can provide more robust flexible electronics. Graphene can have high intrinsic carrier mobility (2000,000 cm² v⁻¹ s⁻¹), high thermal conductivity (˜5000 Wm⁻¹K⁻¹), high Young's module (˜1.0 TPa), and high optical transmittance (˜97.7%). Accordingly, graphene-based contacts and interconnects can be highly conductive (both electrical and thermal), durable, and transparent, allowing promising applications in flexible electronics.

The performance of graphene-based contacts in MoS₂ field effect transistors (FETs) is described. The Fermi level in graphene can be tuned, electrostatically and/or chemically, so as to allow excellent work function match with MoS₂, leading to low contact resistance.

Non-Limiting Example Preparation of Semiconductor Material Layers

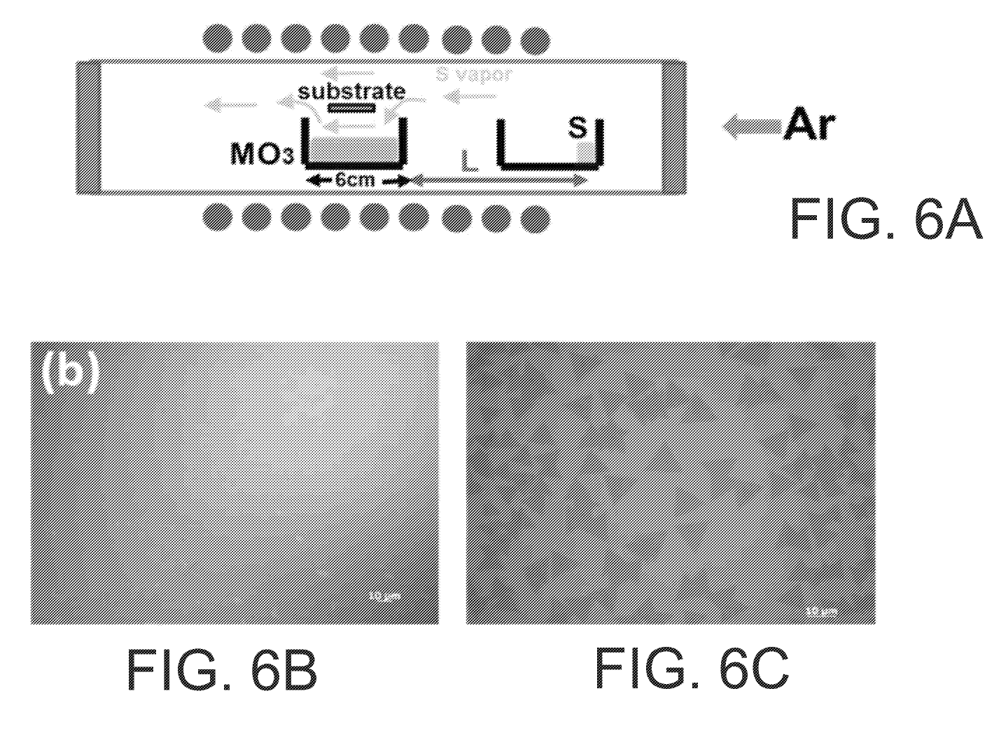

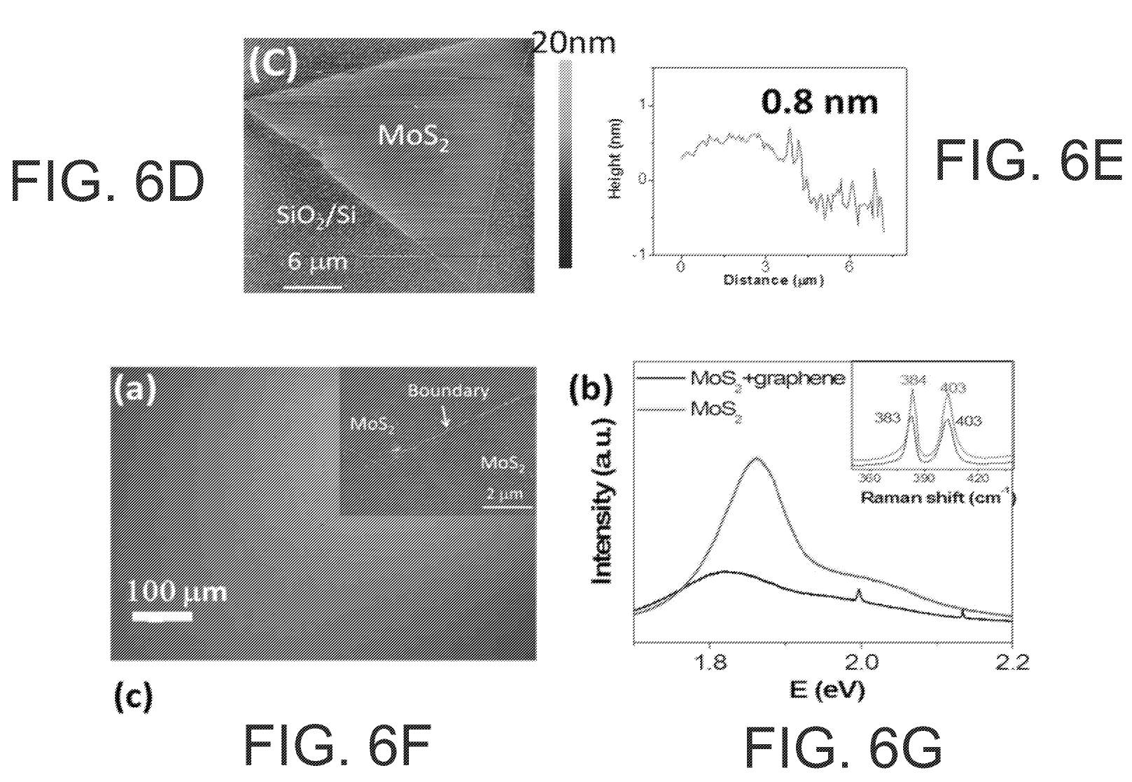

High-quality TMD monolayers, including MoS₂ and WS₂, can be synthesized on diverse surfaces using scalable CVD process with the seeding of perylene-3,4,9,10-tetracarboxylic acid tetrapotassium salt (PTAS). For example, large-area single layer MoS₂ can be grown on a 300 nm thick SiO₂/Si substrate for large-scale electronics. The growth of MoS₂ monolayers can be initiated with the seeding of PTAS on substrate surfaces. In operation, high solubility of PTAS in D.I. water enables a uniform distribution of the seeds on the hydrophilic substrate surfaces. Uniform but small PTAS can be precipitated on the surfaces after drying the water. The treated substrates can be mounted up-side down in a growth furnace, which schematic set-up is shown in FIG. 6A. The MoO₃ powders (0.03 g) and S powders (0.01 g) can be placed in different crucibles, with a distance L of, for example, 10 cm between them. During the growth of MoS₂ layers, the furnace can be heated to a growth temperature of, for example, 650° C. An argon gas flow can be passed through the furnace at a flow rate of 10 sccm, carrying the sulfur vapor, which can reduce the the evaporated MoO₃ powders to form MO₃₋ₓ vapor. The MO₃₋ₓ can react with the sulfur vapor to form MoS₂ upon arriving at the substrate surface. With the seeding of PTAS, the synthesis of MoS₂ tends to form a continuous single layer MoS₂ of a few centimeters with a limited furnace size. A reduced reactant for geometry of the crucible may introduce a discontinuous area full of isolated triangles of MoS₂ films. Without being bound by any theory or mode of operation, the triangular shape of MoS₂ monolayers may come from the single crystal structure of MoS₂.

FIG. 6B and FIG. 6C show the resulting MoS2 layers at different locations on the substrate. The domain size of the sample shown in FIG. 6B and FIG. 6C is 20 μm in average. FIG. 6D shoes a representative atomic force microscopy (AFM) image of a sample MoS₂ monolayer with clear boundaries with the SiO₂/Si substrate. FIG. 6E is a plot of surface height retrieved from the AFM image shown in FIG. 6D. The plot shows that the thickness of CVD MoS₂ monolayers is about 8 Å, consistent with typical values of MoS₂ monolayers.

FIG. 6F shows an optical image of a CVD MoS₂ layer fabricated according to methods described in FIG. 6A. The MoS₂ layer has a good uniformity and a high coverage of ˜95%. The sample is also continuous over a size of 2 cm by 2 cm, ending with isolated triangular MoS₂ at the edge (e.g., FIG. 6D).

Raman and photoluminescence (PL) spectroscopy can be performed using a 532 nm Nd:YAG laser on the MoS₂ sample to investigate the quality of MoS₂. The Raman spectra, which has peaks at about 383 cm⁻¹ and 403 cm⁻¹, further confirms the single-layer signature of the CVD MoS₂ (inset of FIG. 6G). A strong photoluminescence peaks located at 1.88 eV (FIG. 6G), implying a high quality of MoS₂ monolayer, corresponds to the carrier recombination across the direct bandgap of single-layer MoS₂.

Non-Limiting Example Preparation of Graphene-Based Material Layers

Graphene samples can be prepared by, for example, low pressure chemical vapor deposition (LPCVD) process, following a Cu-foil based graphene synthesis process. A Cu foil (e.g., 36 μm-thick) can be used as a catalyst substrate inside the growth chamber (e.g., a quartz tube), flowing with carbon containing gases or gas mixtures, such as CH₄/H₂. An exemplary synthesis temperature and pressure can be 1035° C. and 1.70 Torr, respectively.

For further analysis, the resulting graphene can be transferred onto a 300 nm-thick SiO₂ thermally grown heavily p-doped Si substrate as well as the pre-fabricated MoS₂ sample, by taking advantage of a supporting layer (e.g., a PMMA layer). The synthesis in the growth chamber can generate graphene on both sides of the Cu foil. Therefore, the first step in graphene transfer can be the removal of graphene on the reverse side of the Cu foil via, for example, O₂/He plasma. Then, PMMA (e.g., 495 Microchem A4) as a supporting layer can be spin coated on the graphene/Cu stack, generating a PMMA/graphene/Cu stack, which can be brought onto a Cu etchant (e.g., CE-100, TRANSENE). After etching Cu for an extended period of time (e.g., one hour), the resulting PMMA/graphene stack can be thoroughly rinsed with deionized (DI) water. Further cleaning of the graphene surface can be performed before floating the PMMA/graphene stack in a DI water and transferring onto a SiO₂/Si and MoS₂/SiO₂/Si substrate. To reduce trapping of water molecules between graphene and substrates, Piranha cleaning can be carried out to the substrate in advance in the case of SiO₂. The PMMA/graphene stack transferred on a SiO₂/Si substrate can be then dipped into a solution (e.g., acetone) to selectively remove the PMMA, leaving an intact and conformal graphene sample on the SiO₂/Si and MoS₂/SiO₂/Si substrate.

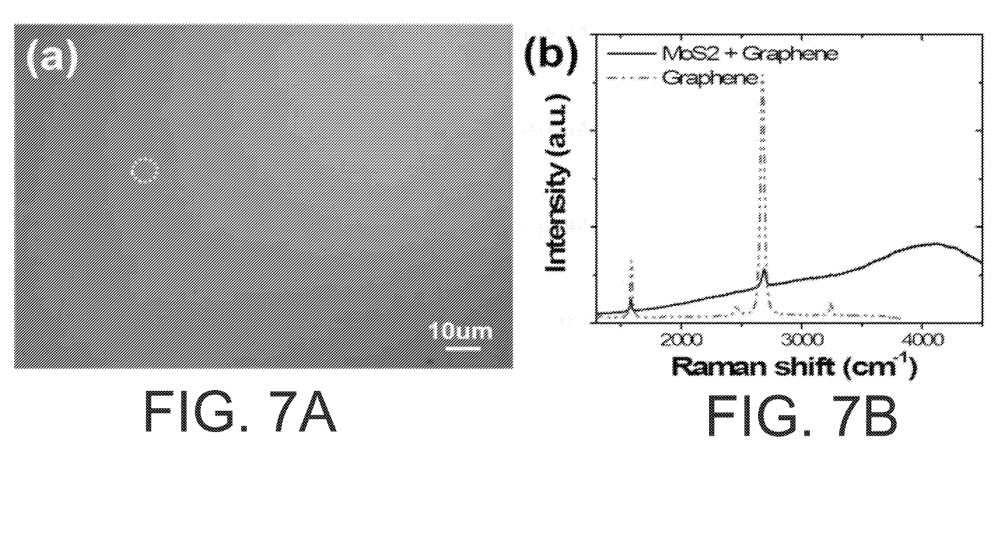

FIG. 7A shows the surface of a graphene sample prepared according to methods illustrated above. The surface of graphene is notably clean with negligible PMMA residue and a small crack (dashed circle).

Quantitative characterization of the graphene quality can be carried out by Raman spectroscopy using a laser beam at 532 nm. A typical Raman spectrum of a graphene can include three bands (or spectral peaks) known as the G-band at 1582 cm⁻¹, the 2D band at ˜2685 cm⁻¹, and the D-band at ˜1350 cm⁻¹.

The G-band is a primary mode in graphene, representing the planar configuration sp² bonded carbon that constitutes graphene. The G-band is resonant, and thus can be very strong in the spectrum. The position of the G-band can provide useful information about the graphene sample. For example, as the layer thickness increases, the G-band position can shift to lower energy probably due to a slight softening of the bonds as the layer thickness increases. Moreover, the position of the G-band can be also related to doping and even very minor strain, allowing precise characterization of the graphene

The D-band in graphene Raman spectra is known as the disorder band or the defect band. It represents a ring breathing mode from sp² carbon rings. The band is the result of a one phonon lattice vibrational process. The intensity of the D-band can be proportional to the level of defects in the sample. The D-band is also a resonant band, exhibiting a dispersive behavior. There can be a number of very weak modes underlying this band and the choice of excitation laser used will enhance different modes. Accordingly, both the position and the shape of the band can vary with different excitation laser frequencies, making it is informative to use the same excitation laser frequency for all measurements when characterizing the D-band.

The 2D-band in graphene Raman spectra is the second order of the D-band, also referred to as an overtone of the D-band, resulting from a two phonon lattice vibrational process. Unlike the D-band, the 2D-band does not need to be activated by proximity to a defect. As a result the 2D-band can be a strong band in graphene even when no D-band is present, and it does not represent defects. The changes in the shape of the 2D-band shape can be related to the active components of the vibration. With single layer graphene, there is usually only one component to the 2D-band; but with bilayer graphene, there can be four components to the 2D-band.

The Raman spectra of graphene/SiO₂/Si (dashed red line in FIG. 7B) shows that this graphene is a single layer, evidenced by the intensity ratio of 2D band to G band (2D/G) as high as about 8. The intensity ratio of D band to G band (D/G) in a Raman spectrum can also be used as an indicator of the defectiveness of graphene, since the D-band normally appearing at 1345 cm⁻¹ can be susceptible to point defects in graphene created by, for example, impurity or interaction with dangling bonds of the substrate. The Raman spectra obtained at 10 locations in the sample show not only negligible absolute D band intensity as shown in FIG. 7B, but a D/G ratio less than 0.1 on average. Therefore, Raman spectra can provide a baseline of the quality of graphene to be used in the fabrication of MoS₂ transistor and circuits. The Raman spectra of graphene/MoS₂/SiO₂/Si is shown as the black line in FIG. 7B. The strong background may come from the photoluminescence of the underneath MoS₂. The position and intensity ratio of G and 2D in graphene have been preserved in graphene/MoS₂/SiO₂/Si structure, demonstrating the high quality of graphene graphene/MoS₂/SiO₂/Si.

Non-Limiting Example Fabrication of Devices including Graphene-Semiconductor Heterostructures

Almost a decade after the first successful isolation of graphene, it remains challenging to bring together more than one type of 2D materials for large-scale device and circuit applications. Main difficulties can include scalable synthesis, transferring of samples, precise stacking of multiple monolayers of high-quality large-area 2D materials, as well as developing a fabrication process that can handle these unique atomically thin heterostructure. Unlike in heterostructures made of III-V semiconductors, it can be hard to perform selective etching of one particular type of 2D material without damaging another type of 2D material when more than one 2D nanosheets are stacked together.

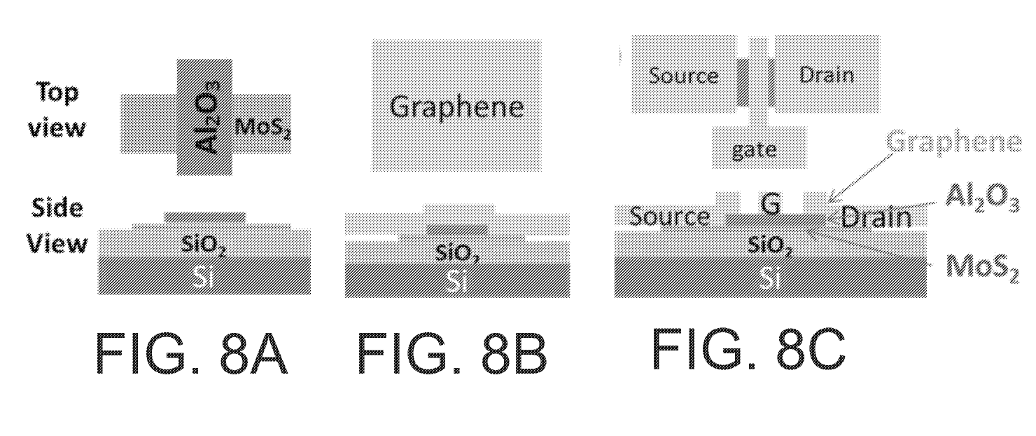

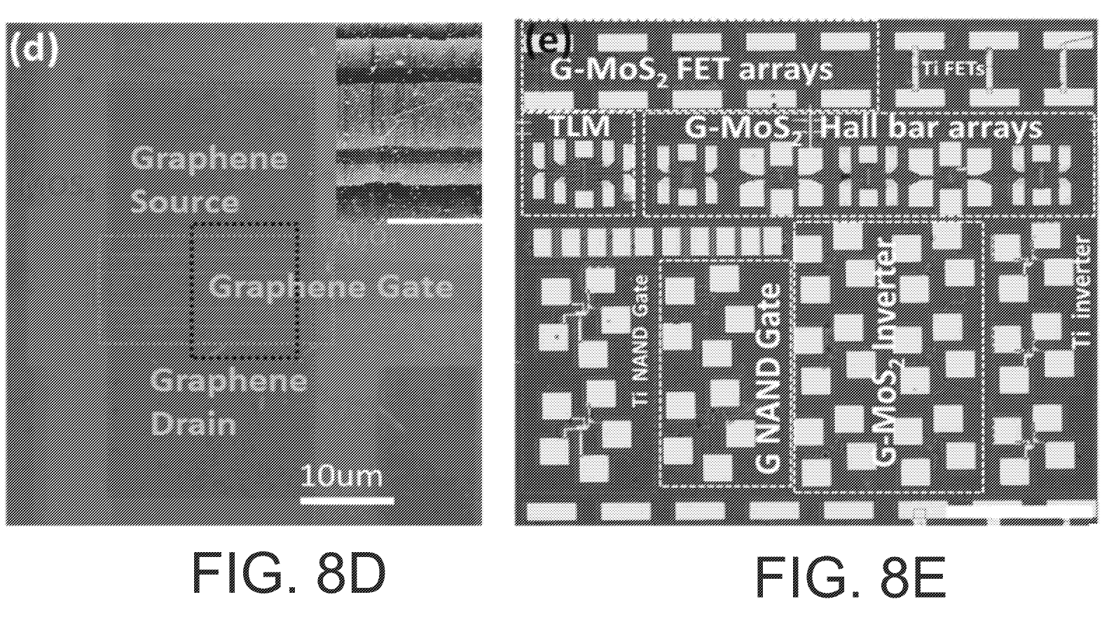

The example systems, apparatus and methods described herein provide a scalable fabrication process that can facilitate construction of atomic-scale graphene/MoS₂ hybrid 2D electronics, as shown in FIG. 8A-8C. In this process, CVD-MoS₂ monolayers grown on a SiO₂/Si substrate can be first patterned to form a channel material for a transistor using, for example, electron beam lithography (EBL) with poly (methyl methacrylate) (PMMA) as the resist. After developing the resist pattern, the exposed parts of the MoS₂ sheet can be etched away using oxygen plasma to achieve device isolation. The sample is then coated with methyl methacrylate (MMA) (6% concentration in ethyl lactate)/PMMA (2% concentration in anisole) stack, followed by EBL exposure and development, forming a double-layer structure with openings on MMA slightly wider than that on PMMA. Subsequently, 20 nm aluminum oxide (Al₂O₃) can be deposited by atomic layer deposition (ALD) at 100° C. (below the glass transition temperature of PMMA/MMA stack) using trimethylaluminum (TMA) and water as precursors (see methods), followed by liftoff to form patterned Al₂O₃ etch-stop layer (FIG. 8A). Large-area single layer graphene grown on copper foils and transferred onto the sample (FIG. 8B) can then be selectively etched by oxygen plasma to define the source, drain and gate of the transistor, following a new EBL step. The MoS₂ channels can be protected by the Al₂O₃ etch stop layer (FIG. 8C) during the etching of the graphene. The resulting sample can be cleaned by acetone and annealed to remove PMMA residues.

The schematic top and side view and the optical micrograph image of a dual gate FETs are shown in FIG. 8A through FIG. 8C. The example device has MoS₂ as channel, ALD Al₂O₃ as top gate dielectric, graphene as source, drain and gate electrodes (connected to metal pads for measurement) and SiO₂/Si as back gate (MoS₂-G FET) (not shown). In FIG. 8D, the single layer graphene and single layer MoS₂ can be distinguished through the optical contrast because of the thin material structure and interference effect between the graphene and MoS₂ with the SiO₂/Si substrate underneath. The orange background, bright blue squares, blue and greyish purple region in FIG. 8D are SiO₂, Al₂O₃, MoS₂ and graphene, respectively. In the AFM image (FIG. 8D, inset) of the channel region (black dashed rectangle in FIG. 8D), the signature wrinkles on the CVD graphene can be found. The surface of the low temperature ALD Al₂O₃ layer is uniform and free of pinhole, with a dielectric thickness of 20 nm as measured by AFM.

Based on this large-scale hybrid structure process, various devices and integrated circuits on a single chip can be fabricated (FIG. 8E). FETs, Hall bars and transmission line method (TLM) structures can be created to characterize the material properties and device performance, while inverters and NAND gates can demonstrate the scalability and the potential of this technology for mass production.

On the same chip (FIG. 8E), a batch of control devices and circuits can also be fabricated with 15 nm Ti/45 nm Au metal stacks as electrodes (MoS₂—Ti devices and circuits) (shown in red dashed-line rectangles in FIG. 8E). The MoS₂—Ti devices and circuits are fabricated with Al₂O₃ as top dielectric layers and Graphene as top gate, in order to eliminate the effect from high-k dielectric and top/back gate couplings when investigating the role of the ohmic contacts.

Non-Limiting Example Performance of Transistors including Graphene-Semiconductor Heterostructures

The fabricated devices and circuits can be measured in a vacuum probe station (Lakeshore cryogenics) at a pressure of ˜3×10⁻⁶ Torr to characterize their performance. During all back gate sweep measurements, the top gates are grounded and vice versa to avoid the coupling between top gates and back gates. About 50 devices are studied and they show highly reproducible performances.

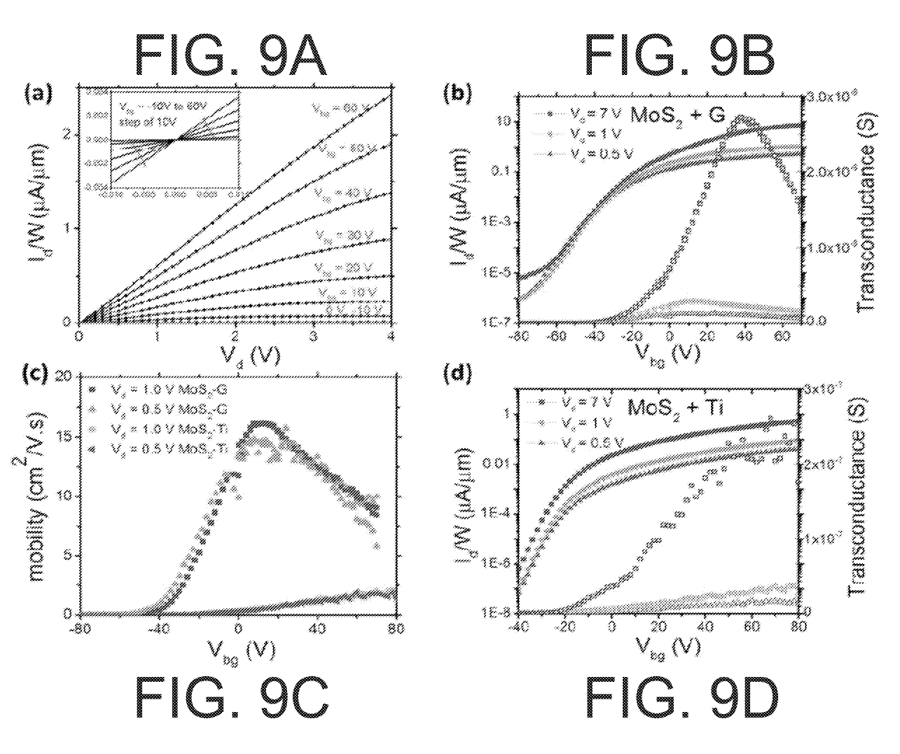

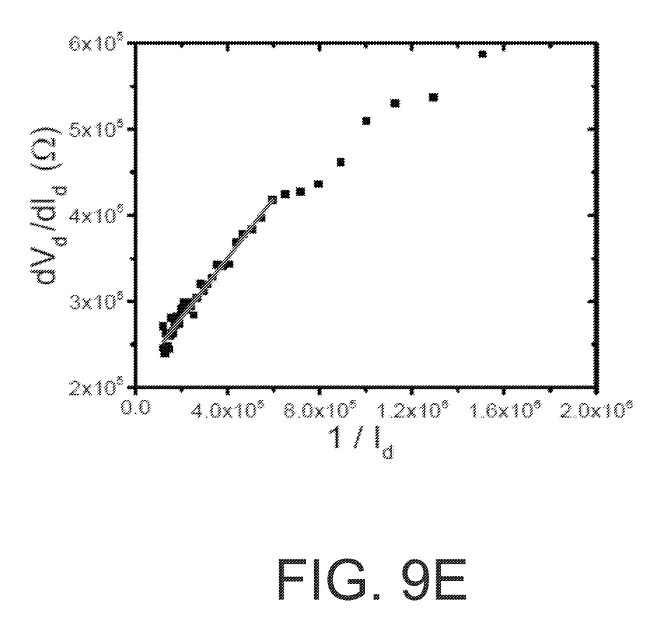

FIG. 9A-9D show representative back-gated transport performance of a MoS₂-G transistor fabricated according to methods illustrated in FIG. 8A-8C. The transistor has a device channel length of 12 μm and width of 20 μm. FIG. 9A shows the output performance (I_{ds}−V_{ds}) of the devices. The current is linear with source-drain voltage at low bias, indicating the contact between graphene and MoS₂ is ohmic. The symmetry of the current with respect to the origin at positive and negative biases (inset of FIG. 9A) further verifies the ohmic nature of the contacts.

The transfer characteristics (I_{ds}−V_{bg}) of MoS₂-G and MoS₂—Ti FETs (controlled devices with exactly the same geometry) are shown in log scale in FIG. 9B and FIG. 9D, respectively. They both have on/off ratios larger than 10⁶. The current density is 8 μA/μm at V_{d}=7 V, V_{bg}=60 V for MoS₂-G FET, about 12 times higher than that of MoS₂—Ti (FIG. 9D), which may be due to the lower barrier between MoS₂ and graphene than that of MoS₂ and Ti.

The transconductance per channel width (gₘ/W=dI_{d}/dV_{bg}/W) of MoS₂-G is 0.15 μS/μm, which may be limited by the small capacitance of the back gate oxide, however, is still more than one order of magnitude higher than that of MoS₂—Ti structures. The carrier mobilities calculated from the transfer characteristics are shown in FIG. 9C. The mobility of MoS₂ in MoS₂-G structures reaches the peak value of 17 cm²/V.s, while MoS₂—Ti structure has a peak mobility of only about 1.8 cm²/V.s. The carrier mobility of MoS₂-G structure could be further improved by elimination of trapping state and using flat substrate such as boron nitride (BN).

In a Schottky diode, when there is serious resistance, the current can be expressed as:

I_{d}=Iₛ*(exp(q(V_{d}−I_{d}*Rₛ)/nκ_{B}T)−1)

Where Rs is the serious resistance:

$${V}_{d} = {I}_{d} * {R}_{s} + \frac{n {κ}_{B} T}{q} * ln ( \frac{{I}_{d}}{{I}_{s}} + 1 )$$

### Thus

$$\frac{d {V}_{d}}{d {I}_{d}} = {R}_{s} + \frac{n {κ}_{B} T}{q} * \frac{1}{{I}_{d}}$$

In the plot of

$$\frac{d {V}_{d}}{d {I}_{d}} \sim \frac{1}{{I}_{d}} ,$$

as shown in FIG. 9E, the intercept is Rₛ and the slope is

$$\frac{n {κ}_{B} T}{q} .$$

Using this method, n and Rₛ for each back gate voltage can be calculated. FIG. 9E is an example of the fitting with V_{bg}=40V and from this Figure we can get Rₛ=212 kohm and n of 13.4.

The measured I-V characteristics can be fitted to a classic drift-diffusion model to extract the contact resistance for MoS₂-G and MoS₂—Ti FETs. Without being bound by any theory or mode of operation, the effective gate voltage V_{gs}_{_}_{eff} and source drain voltage V_{ds}_{_}_{eff} are given by V_{gs}_{_}_{eff}=V_{gs}−Rₛ×I_{ds} and V_{gs}_{_}_{eff}=V_{gs}−(Rₛ+R_{d})×I_{ds}, considering the parasitic series source/drain contact resistance, Rₛ and R_{d}. The contact resistance is 0.1 kΩ.mm and 1 kΩ.mm for MoS₂-G and MoS₂—Ti, respectively. The smaller effective threshold (Vₜ_{_}_{eff}=Vₜ₀+Rₛ×I_{ds}) in MoS₂-G FETs can also evidence the smaller resistances there. The single layer MoS₂ has larger bandgap than multilayer MoS₂ and the CVD sample has lower doping concentration than flakes, thus it can be more difficult to make good contacts to single layer CVD MoS₂ compared to multi-layer flakes which have been studied before.

The use of graphene as contacts for MoS₂ FETs can provide 10 times lower contact resistance, 10 times higher on-current and field effect mobility than conventional MoS₂-metal contacts. This new contact scheme may also benefit flexible electronics, where most failures of current devices are due to crack formation in the metal electrodes. In addition, the commonly used sputtering process, which can be not compatible with fragile single-layer MoS₂, can be avoided, allowing noninvasive solution for transparent electrode.

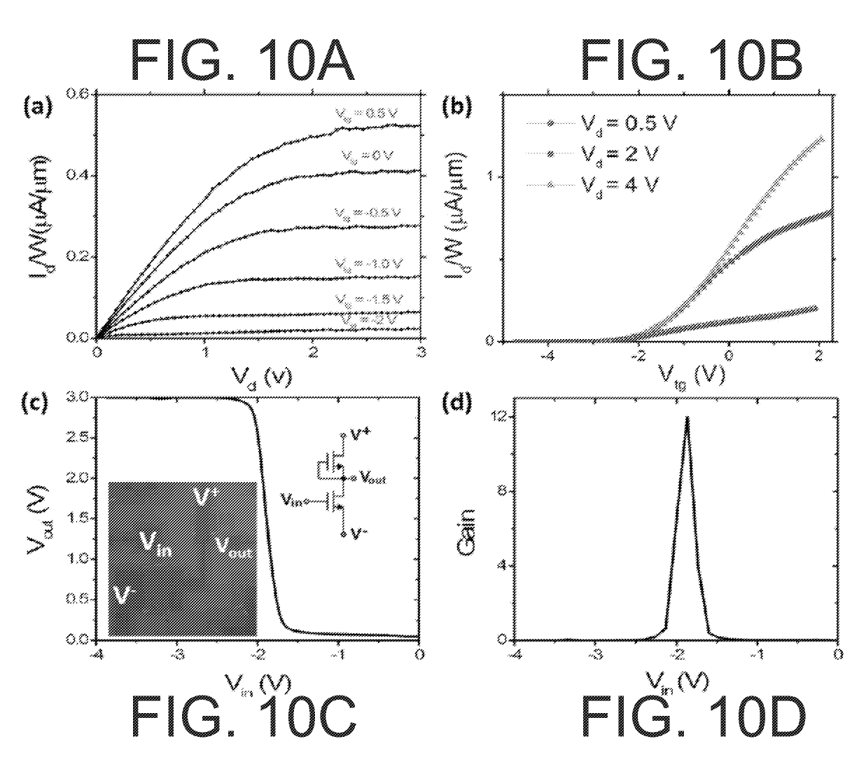

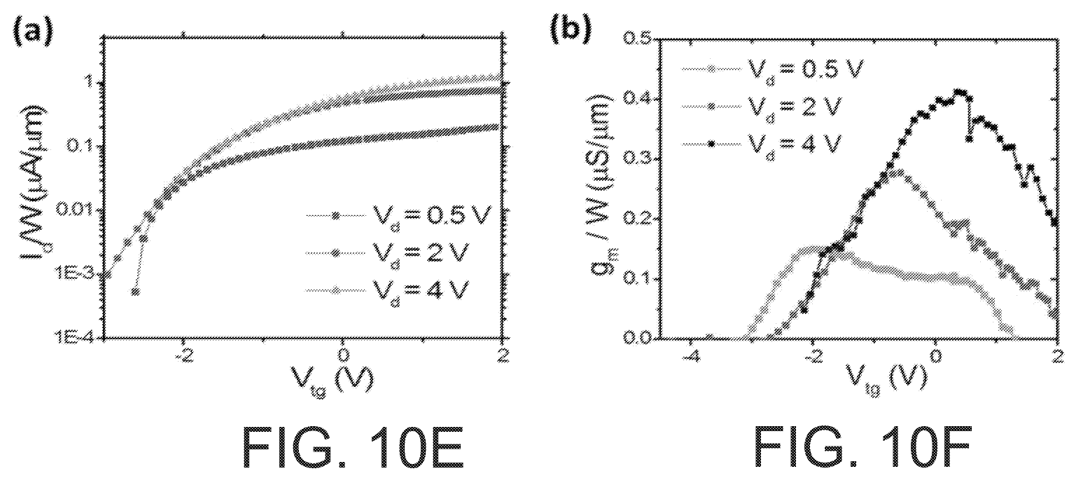

The top-gated performance of the graphene-MoS₂ transistors is plotted in FIG. 10A-D. The output characteristics show a linear current behavior at low drain bias voltages, and current saturation at higher biases. The onset for current saturation follows the relationship V_{ds}=V_{tg}−Vₜ with Vₜ=−1.7 V. The transfer characteristics are shown in FIG. 10B. The results show the on-off ratio of the device is larger than 10³. The transconductance in this device is 0.5 μS/μm for V_{d}=7 V (see, e.g., FIG. 10E). The transconductance drops at the high gate voltage region, possibly due to an access resistance. The subthreshold swing (SS) is 150 mV/dec (see, e.g., FIG. 10F), corresponding to a mid-gap interface trap density (Dᵢₜ) value of 2.7×10¹² cm⁻² eV⁻¹ using Cₒₓ calculated from 20 nm-thick Al₂O₃ with a dielectric constant of 7.

Non-Limiting Example Integrated Circuits Based on Graphene-Semiconductor Heterostructures

Based on the technology and the transistors described above, various integrated logic circuits can be constructed. For example, a fully integrated inverter can be fabricated in depletion mode resistor configuration, using two MoS₂-G FETs (FIG. 10C). In operation, the two transistors act as a switching and a load resistor, respectively (schematic diagram, FIG. 10C). The output characteristics of the inverter are shown in FIG. 10D. A low voltage of −4 V represents a logic state 0 and a voltage close to 0 V represents logic state 1. Similar to the inverters with Ti/Au contacts, an optimization of dielectric and the doping concentration are desirable to get positive threshold voltage and positive input voltage. The inverter is able to be operated under a supply voltage (V_{dd}) of 3V, as shown in FIG. 10C. The voltage gain is close to 12 (FIG. 10D). Performance may be increased by changing the dielectric layers to insulating 2D crystals such as but not limited to BN or 2D oxides.

Non-Limiting Example of Tuning the Schottky Barrier Height of a Graphene-Semiconductor Heterostructure

The results from the transistors and circuits based on graphene-semiconductor heterostructure demonstrate the advantage of a graphene-based material as a contact material for electronic systems, such as but not limited to 2D electronic systems, 3D electronic systems, and other forms of integrated electronic systems. They also highlight the role of the interfacial barrier height between the active channel and electrodes in device performance. Systematic analysis and computations of the barrier in a non-limiting example MoS₂-graphene heterostructure is provided as examples of direct device design. For comparison, analysis and computations for an example MoS₂—Ti structure is also provided.

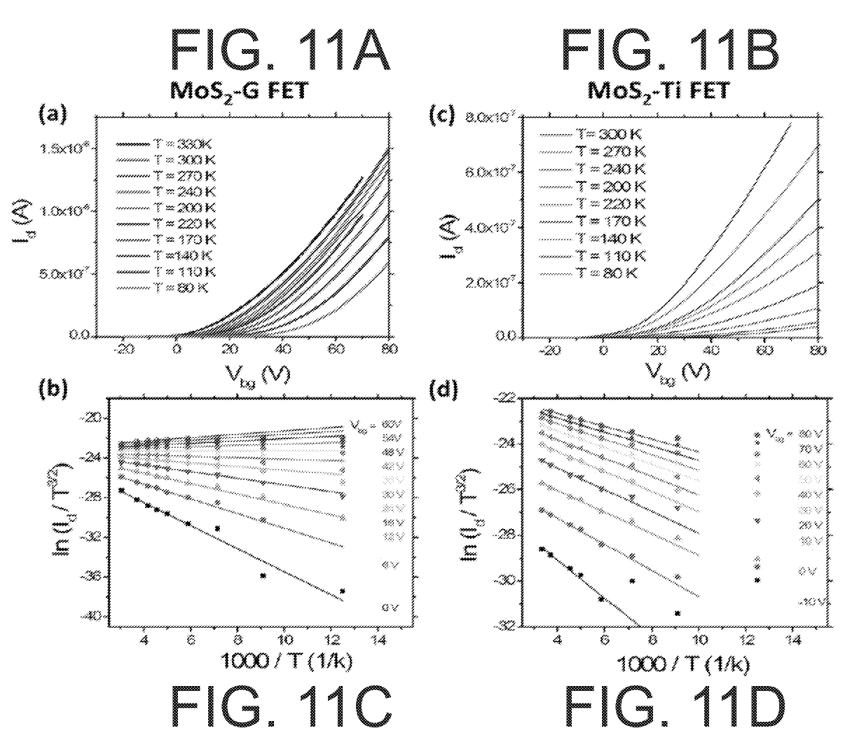

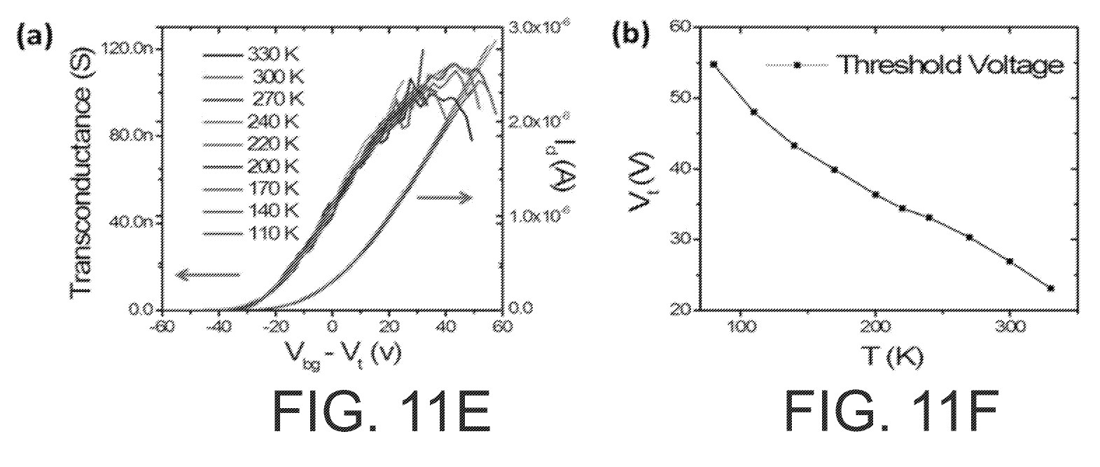

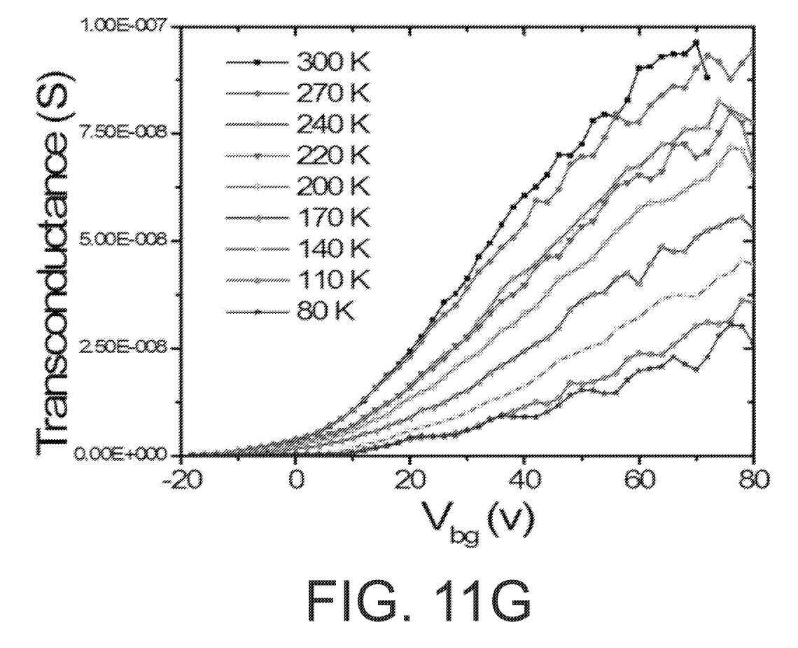

Transport performances of both structures with different temperatures can be investigated and modeled using thermal emission with a Schottky barrier, as shown in FIG. 11A-11D. Without being bound by any theory, the current through a Schottky barrier into 2D material can be described using the 2D thermal emission equation:

I_{d}=AT^{3/2}*exp(q(−qφ_{B}/κ_{B}T)*(exp(qV_{d}/nκ_{B}T)−1)=Iₛ*(exp(qV_{d}/nκ_{B}T)−1)

In this equation I_{d} is the current, A is Richardson's constant, T is the temperature, φ_{B} is the barrier between metal and semiconductor, κ_{B} is the Boltzmann constant, q is the electronic charge, V_{d} is the source to drain bias and n is the non-ideal factor of the Schottky diode. The power of T^{3/2} can come from the Boltzmann carrier distribution and the thermal velocity. It is reduced from T² of 3D system because of the constant density of state in 2D system. n can be calculated by fitting I_{d}−V_{d} curves using expression of

I_{d}=Iₛ*(exp(q(V_{d}−I_{d}*Rₛ)/nκ_{B}T)−1),

where Rₛ is the series resistance from the device channel.

The current as function of back gate bias of MoS₂-G and MoS₂—Ti FETs with different temperature are shown in FIG. 11A-11D. Qualitatively, for both structures, the current decreases when the temperature decreases. However, the quantitative behavior can be different. The temperature dependence of current in MoS₂-G is weaker than that of MoS₂—Ti at high gate voltage, indicating less thermal emission barrier in MoS₂-G structure. In MoS₂-G, the threshold voltage shifts to more positive values with decreasing temperature (see, e.g., FIG. 11E-11F) and the mobility keep almost constant with the same gate overdrive of V_{bg}−Vₜ. In MoS₂—Ti structure, the threshold voltage does not change, while the transconductance or mobility decreases with decreasing temperature (see, e.g, FIG. 11G).

To determine Schottky barrier height (SHB), ln

$$( \frac{{I}_{d}}{{T}^{3 / 2}} )$$

can be plotted against

$$\frac{1}{T}$$

for various V_{bg} as shown in FIG. 11A and FIG. 11D for MoS₂-G and MoS₂—Ti respectively. When

$${V}_{d} \geq 3 {κ}_{B} T / q ln ( \frac{{I}_{d}}{{T}^{3 / 2}} ) = - \frac{q ( {ϕ}_{B} - {V}_{d} / n )}{{κ}_{B} T} + ln ( A )$$

The effective Schottky barrier height (SHB) can be extracted from the slope of ln

$$( \frac{{I}_{d}}{{T}^{3 / 2}} ) - \frac{1}{T}$$

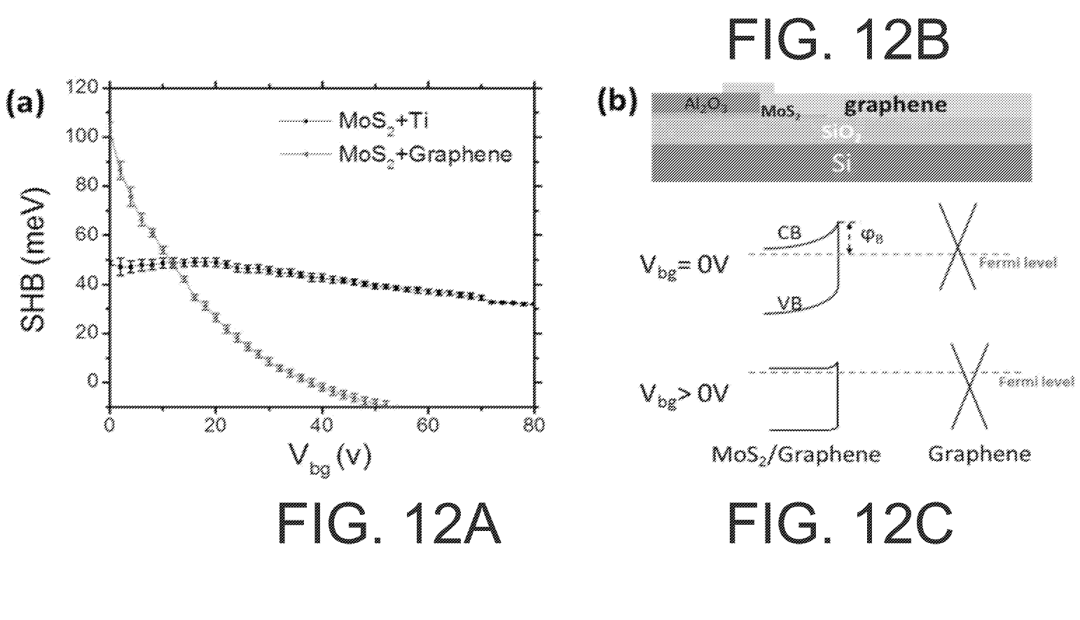

plus the n value acquired from I_{d}−V_{d} fitting, whose values are shown in FIG. 12A-12C. The agreement over all the temperatures can be evidenced by the small error bar values.

In MoS₂-G structures, the SBH decreases dramatically from 110 meV to 0 meV with back gate changing from 0 V to 35 V. On the other hand, the SHB in MoS₂—Ti has relatively weak dependence with back gate voltage, changing from 50 meV to 40 meV with back gate from 0 to 80 V.

In general, the Schottky barrier height (φ_{B}) can be determined by the difference between work function of the metal (Wₘ), the affinity of the semiconductor (χₛ) and surface potential (φₛ), that is, φ_{B}=Wₘ−χₛ+φₛ. The change of φ_{B} in MoS₂-G can come from changes of Wₘ and φₛ. In MoS₂—Ti the modulation can be limited, only from that of φₛ (possibly mid-gap interfacial state), just like in conventional metal-semiconductor junctions. The work function of graphene can be modulated by electric field, following the expression:

Wₘ=E_{F}=−sgn(n₀)Ø v_{F}\sqrt{π|n₀|}, n₀=q(V_{bg}−Vₜ)

where n₀ is the carrier concentration in graphene, Ø the reduced Planck constant and v_{F} the Fermi velocity. It can be found that 30 V change in V_{bg} with 300 nm SiO₂ as back gate dielectric can induce changes of around 200 mV in the graphene work function, which is consistent with the change in the Schottky barrier height observed above. The electric field seen by graphene in the electrode part can be partially screened by MoS₂, while graphene in interconnects part are directly modulated by 285 nm SiO₂. As a result of this modulation, when the back gate voltage is larger than 35 V, the Schottky barrier height between MoS₂ and graphene can be zero, forming an ohmic contact at the MoS₂/graphene junction. The finite density of states and the tunability of its work function make graphene capable of forming efficient contacts with MoS₂ and other semiconductors, offering new opportunities to design contact and engineering junction interfaces.

Further analysis of MoS₂-G heterostructure can be performed by first-principles total-energy calculations using density functional theory.

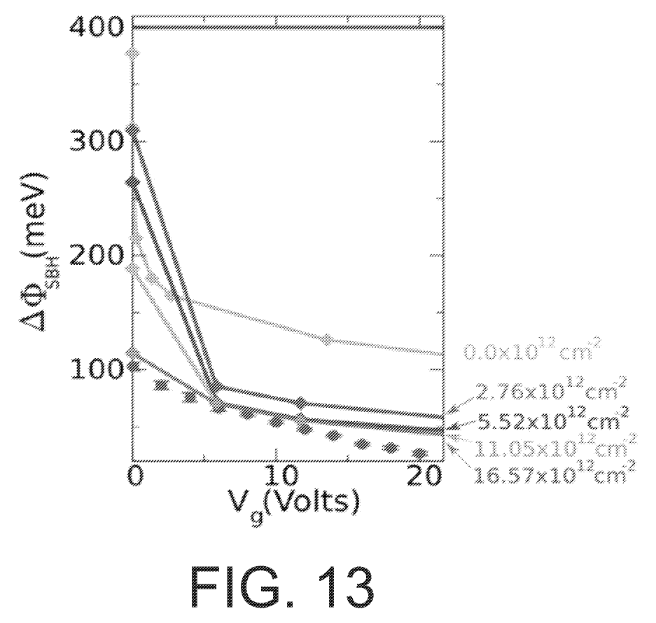

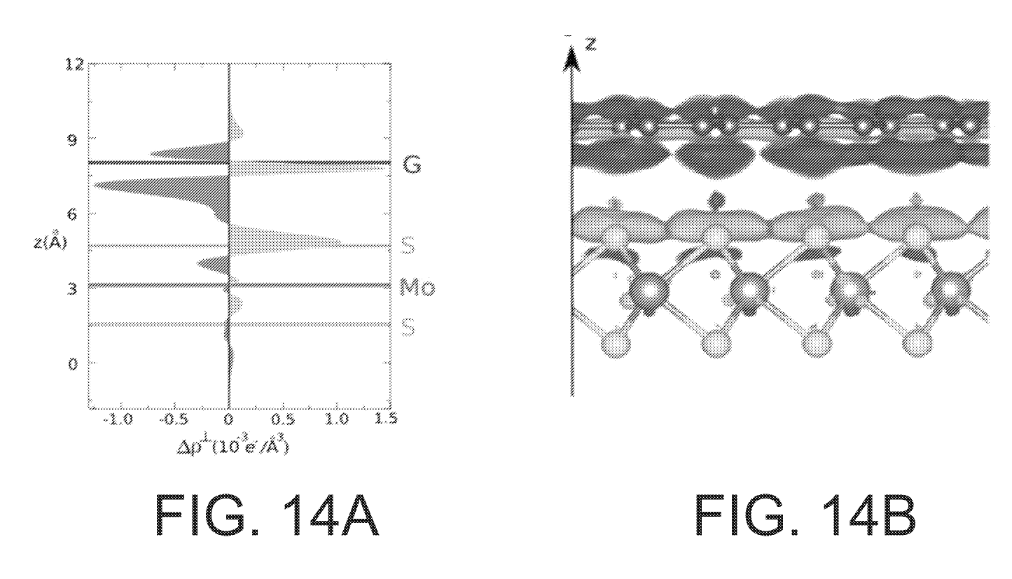

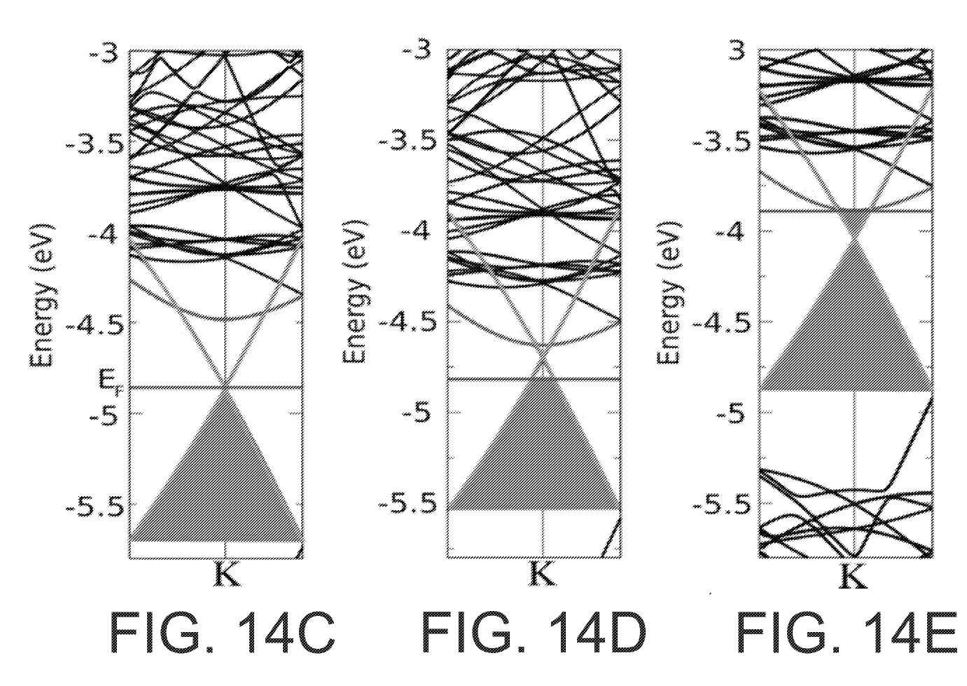

FIG. 13 shows calculated Schottky barrier (ΔΦ_{SBH}) with respect to the electric gate bias at different doping levels. The electric gate can be simulated through a saw-tooth-like potential perpendicular to the MoS₂-G plane. The different doping levels are obtained by adding certain amount of electrons to the system and imposing a compensating uniform background in order to converge the total energy and the long-range Coulomb interactions. In the computations, the vertical contact barriers are addressed. In this case, the barrier can be given by the difference between the Fermi level of the combined system, assuming the electronic equilibrium is reached, and the conduction band minimum of MoS₂ at the K point in the Brillouin zone (see FIG. 14A-14C). At zero doping and electric bias, the barrier height is 385 meV, which is close to the experimental value of 400 meV from the energy level difference between the work function of graphene (4.5 eV) and the electron affinity of MoS₂ (4.1 eV).

As smaller amounts of charge doping is introduced into the system, strong variations of ΔΦ_{SBH} are observed, which changes the offset position of the curves at zero voltage. Once the electric bias is switched on, ΔΦ_{SBH} can be modulated by the electric field, inducing a damping of the barrier height that depends, at least in part, on the doping level of the system. Without being bound by any theory, the initial strong dependence of the damping of ΔΦ_{SBH} on the gate voltage can be due to the very low density of states near the graphene Dirac point, which results in large shift of the Fermi level in response to a small amount of induced charge. Beyond 6 Volts of the gate voltage, the change in ΔΦ_{SBH} slows down, and become almost independent of the doping level at high concentrations. This can be a doping-driven effect that is observed to saturate at densities close to ˜10¹³ cm⁻².

FIGS. 14A-14C shows the charge difference Δρ^{⊥} plane-averaged perpendicular to the interface (FIG. 14A), and the respective isosurfaces (FIG. 14B). The faint blue regions represent accumulation, and the red regions represent the depletion of electrons in the combined system relative to the two isolated components. In the calculation, the atomic positions of the respective layers have been frozen as obtained in the combined situation. The first layer of S atoms and the G layer have a net charge accumulation, which in comparison with typical metallic substrates, for instance Ti, shows a substantial enhancement. This can enable better charge injection at the interface which determines the low bias transport. Moreover, the metallization of the interface can be due to graphene states mainly of 2p_{z} character (see FIG. 14B) present at the Dirac cone close to the Fermi energy. These states are shown in FIG. 14C through the calculated band structure of the MoS₂-G heterostructure in the limit of zero doping, that is, the Fermi level of the system is at the Dirac point. The graphene states are observed inside the MoS₂ gap which can provide, on the one hand, energy levels needed to a better electronic transport, and on the other hand, the creation of a Schottky barrier at the metal-semiconductor interface as discussed above.

The effect of doping and an external electric bias can also be appreciated in the interface as plotted in FIG. 14D-14E, respectively. Because of the very small density of states near the graphene Dirac point, the behavior of the device can be sensitive to position of E_{F} inside of the band gap. At finite doping or electric fields, E_{F} can shift away from the Dirac point, inducing modifications on the relative position of the band edges in relative to the neutrality point. This can change the magnitude of the Schottky barrier height, which can be calculated as the difference between the Fermi level of the heterostructure and the conduction band minimum of MoS₂ at the K point in the Brillouin zone. A damping of the barrier can be induced as a function of the gate bias. In the limit of high bias and finite doping (FIG. 14E), the barrier height can converge to zero with the Fermi level localized at the bottom of the conduction band of the MoS₂ layer.

Non-Limiting Example Electronics Including Graphene-Semiconductor Heterostructures

Systems, apparatus and methods according to the principles described herein include various electronics including of any one or more of the example graphene-based electrode-semiconductor material heterostructures described hereinabove.

As a non-limiting example, the graphene-based electrode-semiconductor material heterostructures can be configured as a portion of a p-n junction device, a light-emitting device (LED), a bolometer, a solar cell, or a laser.

As a non-limiting example, the graphene-based electrode-semiconductor material heterostructures can be configured as a portion of a transistor, such as but not limited to thin-film transistors, or as a portion of an apparatus that includes these transistors. Any graphene-based electrode-semiconductor material heterostructure described hereinabove can be configured as a portion of an electronic component that is arranged as a separately addressable element in an array of separately addressable elements.

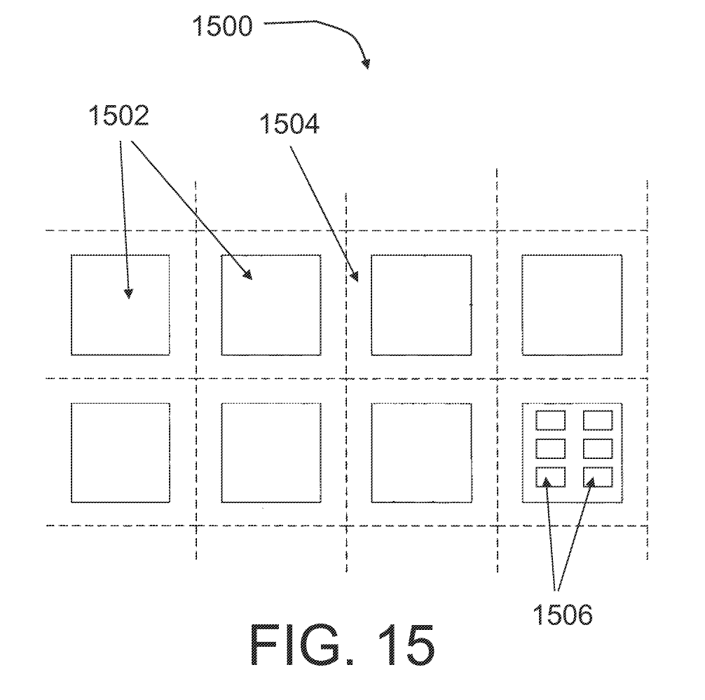

As a non-limiting example, the graphene-based electrode-semiconductor material heterostructures can be configured as a portion of a sensor. An example sensor can be configured as including one or more arrays of sensor elements, each sensor element being coupled with at least one transistor. For example, as shown in FIG. 15, a sensor array can include one or more sensor regions 1500, each sensor region including an array of sensor elements 1502. Each sensor element 1502 can include one or more transistor, or a plurality of transistors. The sensor array may also include regions 1504 that do not include sensor elements. In an example implementation, sensor elements 1502 can be formed as pixels of an image sensor. In other example implementations, sensor elements 1502 can be formed as other types of sensors, including chemical sensors, pressure sensors, electrical sensors, and environmental sensors. In an example implementation, sensor elements 1502 can be included as a portion of a sensor in a biological system, such as but not limited to a heart rate sensor, an electrical activity sensor, a temperature sensor, a neural activity sensor, or a conductance sensor.

Flexible thin-film transistors and other thin-film semiconductor devices including graphene-based electrode-semiconductor material heterostructures according to the principles herein can provide flexible electronics that are lightweight, rugged, bendable, rollable, portable, and potentially foldable. They find applications in a wide range of areas, including flexible displays (e.g., wearable computer, invisible cloak, and E-paper), health care (e.g., noninvasive monitoring, control and interaction, drug delivery, and artificial organ), energy generation and storage (e.g., flexible solar cell, supercapacitor, and self-sustainable system), and wireless systems (radio frequency identification tags, data sharing, and seamless operation of communication systems), among others. The advances in flexible electronics based on the graphene-based electrode-semiconductor material heterostructures described herein can exploit the development of other thin film materials, including materials such as aluminum, silicon, germanium and silver, as well as emerging low-dimensional materials such as nanowires, quantum dots and nanotubes.

Any example system, apparatus, and method described herein facilitates large-scale heterogeneous integration of 2D materials in flexible devices. In an example implementation, integrated graphene-semiconductor heterostructures in large scale can be fabricated using a scalable synthetic process of chemical vapor deposition (CVD). In a non-limiting example, the graphene-semiconductor heterostructure can be a graphene/molybdenum disulfide (MoS₂) heterostructure. Transistor devices and logic circuits with MoS₂ channel and graphene as contacts and interconnects can be constructed using any example systems, apparatus, and methods described herein.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments of the invention can be implemented in any of numerous ways. For example, some embodiments may be implemented using hardware, software or a combination thereof. When any aspect of an embodiment is implemented at least in part in software, the software code can be executed on any suitable processor or collection of processors, whether provided in a single computer or distributed among multiple computers.

In this respect, various aspects of the invention may be embodied at least in part as a computer readable storage medium (or multiple computer readable storage media) (e.g., a computer memory, one or more floppy disks, compact disks, optical disks, magnetic tapes, flash memories, circuit configurations in Field Programmable Gate Arrays or other semiconductor devices, or other tangible computer storage medium or non-transitory medium) encoded with one or more programs that, when executed on one or more computers or other processors, perform methods that implement the various embodiments of the technology discussed above. The computer readable medium or media can be transportable, such that the program or programs stored thereon can be loaded onto one or more different computers or other processors to implement various aspects of the present technology as discussed above.

The terms “program” or “software” are used herein in a generic sense to refer to any type of computer code or set of computer-executable instructions that can be employed to program a computer or other processor to implement various aspects of the present technology as discussed above. Additionally, it should be appreciated that according to one aspect of this embodiment, one or more computer programs that when executed perform methods of the present technology need not reside on a single computer or processor, but may be distributed in a modular fashion amongst a number of different computers or processors to implement various aspects of the present technology.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A device comprising:
a semiconductor material layer;
at least one graphene-based electrode, disposed over a portion of the semiconductor material layer, such that the at least one graphene-based electrode forms an overlap region with the semiconductor material layer; and
a means for providing charge carriers in the at least one graphene-based electrode proximate to the overlap region, to reduce a difference between a work function of the at least one graphene-based electrode and either (i) the energy of the electronic conduction band of the semiconductor material layer or (ii) the energy of the electronic valence band of the semiconductor material layer.

2. The device of claim 1, wherein the means for providing the charge carriers comprises a conductive electrode disposed in electrical communication with the at least one graphene-based electrode.

3. The device of claim 1, wherein the means for providing the charge carriers comprises an amount of a dopant provided in at least a portion of the at least one graphene-based electrode.

4. The device of claim 3, wherein the dopant is an acceptor dopant or a donor dopant.

5. The device of claim 3 or 4, wherein the dopant comprises at least one of H₂SO₄, HCl, HNO₃, AuCl₃, FeCl₃, MoCl₂, PdCl₂, N-phenyl-bis(trifluoromethane sulfonyl)imide (PTFSI), silver bis(trifluoromethane sulfonyl)imide (STFSI), bis(trifluoromethane sulfonyl)amine, 1,5-naphthalenediamine (Na-NH2), 9,10-dimethylanthracene (An-CH3), 9,10-dibromoanthracene (An-Br), and tetrasodium 1,3,6,8-pyrenetetrasulfonic acid (TPA), hydrazine (N₂H₄), MoO₃, ReO₃, Rb₂CO₃, Cs₂CO₃, potassium, and aluminum oxide.

6. The device of any of claims 1-5, wherein the semiconductor material layer comprises at least one of a bulk semiconductor material, a layered semiconductor material, a wide-bandgap semiconductor material, a p-n junction, or a heterojunction of at least two materials having different work functions.

7. The device of any of claims 1-6, wherein the at least one graphene-based electrode comprises at least one of a micro exfoliated graphene material, a chemical vapor deposition grown graphene material, and a liquid phase exfoliated graphene material.

8. The device of any of claims 1-8, wherein the at least one graphene-based electrode is a single-layered graphene electrode or a multi-layered graphene electrode.

9. The device of any of claims 1-9, wherein the at least one graphene-based electrode comprises an intrinsic graphene material or a doped graphene material.

10. The device of any of claims 1-9, wherein the charge carriers are holes or electrons.

11. The device of claim 1, wherein the means for providing charge carriers is using a direct synthesis technique, or using a post treatment technique.

12. The device of claim 11, wherein the post treatment technique comprises electrostatic doping, a plasma treatment, an oxide deposition, a molecule deposition, a gas phase annealing technique, substrate engineering, dipping, or coating in a wet chemical.

13. The device of claim 12, wherein the wet chemical is an acid, a base, a metal chloride, or an organic material.

14. The device of any of claims 1-13, wherein the semiconductor material layer is a portion of a transistor device structure, a p-n junction device, a light-emitting device (LED), a bolometer, a solar cell, a sensor, or a laser.

15. The device of any of claims 1-13, further comprising a gate electrode in electrical communication with the semiconductor material layer and spaced apart from the at least one graphene-based electrode.

16. A device comprising:
a semiconductor material layer;
a first graphene-based electrode in electrical communication with a first portion of the semiconductor material layer such the first graphene-based electrode forms a first overlap region with the semiconductor material layer,
wherein the first graphene-based electrode comprises an amount of a first dopant proximate to the first overlap region in a first concentration that reduces a Schottky barrier height between the semiconductor material layer and the first graphene-based electrode; and
a second graphene-based electrode in electrical communication with a second portion of the semiconductor material layer different from the first portion, such that the second graphene-based electrode forms a second overlap region with the semiconductor material layer,
wherein the second graphene-based electrode comprises an amount of a second dopant proximate to the second overlap region in a second concentration that reduces a Schottky barrier height between the semiconductor material layer and the second graphene-based electrode.

17. The device of claim 16, wherein the first dopant or the second dopant comprises at least one of H₂SO₄, HCl, HNO₃, AuCl₃, FeCl₃, MoCl₂, PdCl₂, N-phenyl-bis(trifluoromethane sulfonyl)imide (PTFSI), silver bis(trifluoromethane sulfonyl)imide (STFSI), bis(trifluoromethane sulfonyl)amine, 1,5-naphthalenediamine (Na-NH2), 9,10-dimethylanthracene (An-CH3), 9,10-dibromoanthracene (An-Br), and tetrasodium 1,3,6,8-pyrenetetrasulfonic acid (TPA), hydrazine (N₂H₄), MoO₃, ReO₃, Rb₂CO₃, Cs₂CO₃, potassium, and aluminum oxide.

18. The device of claim 16 or 17, wherein the semiconductor material layer comprises a p-n junction, wherein the first graphene-based electrode forms the first overlap region with the p-doped portion of the semiconductor material layer, and wherein the second graphene-based electrode forms the second overlap region with the n-doped portion of the semiconductor material layer.

19. The device of claim 18, wherein the first dopant is a p-type dopant, and wherein the second dopant is a n-type dopant.

20. A device comprising:
a semiconductor material layer;
a first graphene-based electrode in electrical communication with a first portion of the semiconductor material layer such the first graphene-based electrode forms a first overlap region with the semiconductor material layer;
a dielectric material disposed over the first graphene-based electrode;
a first conductive electrode in electrical communication with the dielectric material,
to apply a non-zero potential difference at the first overlap region to modify a first carrier concentration of the first graphene-based electrode and modify a Schottky barrier height between the semiconductor material layer and the first graphene-based electrode; and
a second conductive electrode disposed over a second portion of the semiconductor material.

21. The device of claim 20, wherein at least one of the first conductive electrode and the second conductive electrode comprises gold, palladium, platinum, copper, tantalum, tin, tungsten, titanium, tungsten, cobalt, chromium, silver, nickel, aluminum, heavily doped silicon, poly-silicon, or any combination thereof.

22. The device of claim 20 or 21, further comprising a second graphene-based electrode disposed between the second conductive electrode and the second portion of the semiconductor material layer,
wherein the second graphene-based electrode is in electrical communication with the second portion of the semiconductor material layer such the second conductive electrode forms a second overlap region with the semiconductor material layer,
wherein the semiconductor material layer comprises a p-n junction,
wherein the first graphene-based electrode forms the first overlap region with the n-doped portion of the semiconductor material layer, and
wherein the second graphene-based electrode forms the second overlap region with the p-doped portion of the semiconductor material layer.

23. The device of claim 22, further comprising:
a first dielectric material disposed between the first graphene-based electrode and the first conductive electrode; and
a second dielectric material disposed between the second graphene-based electrode and the second conductive electrode.

24. The device of claim 22 or 23, further comprising:
a means to apply a positive voltage the first conductive electrode; and
a means to apply a negative voltage to the second conductive electrode.

25. The device of claim 20, further comprising a dielectric material disposed between the second conductive electrode and the second portion of the semiconductor material layer, wherein the second conductive electrode is a gate electrode.
